(19) United States
(12) Patent Application Publication
(10) Pub. No.: US 2024/0152064 A1
(43) Pub. Date: May 9, 2024

(54) PHOTOLITHOGRAPHY METHOD AND METHOD OF MANUFACTURING A SEMICONDUCTOR DEVICE USING THE SAME

(71) Applicant: SAMSUNG ELECTRONICS CO., LTD., Suwon-si (KR)

(72) Inventors: Mincheol KWAK, Suwon-si (KR); Jeongjin LEE, Suwon-si (KR); Seungyoon LEE, Suwon-si (KR); Chan HWANG, Suwon-si (KR)

(21) Appl. No.: 18/372,296

(22) Filed: Sep. 25, 2023

(30) Foreign Application Priority Data
Nov. 4, 2022 (KR) 10-2022-0146326

(51) Int. Cl. G03F 9/00; G03F 7/00; H01L 21/027

(52) U.S. Cl. CPC G03F 9/7073; G03F 7/70141; H01L 21/027; H01L 21/31144

(57) ABSTRACT

A photolithography system includes a light source, a photomask stage, a projection optical system and a wafer stage, and the projection optical system includes an anamorphic lens. In a photolithography method, a wafer and a photomask are mounted on the wafer stage and the photomask stage, respectively, and a first exposure process is performed using the photomask to transfer layouts of patterns included in the photomask to a first half field of the wafer. A relative position of the photomask with respect to the wafer is changed, and a second exposure process is performed to transfer the layouts of the patterns included in the photomask to a second half field of the wafer.

### CROSS-REFERENCE TO RELATED APPLICATION

This application claims priority under 35 U.S.C. § 119 to Korean Patent Application No. 10-2022-0146326 filed on Nov. 4, 2022 in the Korean Intellectual Property Office, the disclosure of which is hereby incorporated by reference in its entirety.

### BACKGROUND

### 1. Field

Example embodiments relate to a photolithography method and a method of manufacturing a semiconductor device using the same.

### 2. Description of the Related Art

A photoresist pattern serving as an etching mask in a method of manufacturing a semiconductor device may be formed by performing an exposing process and a developing process on a photoresist layer, and an etching object layer may be etched using the photoresist pattern as an etching mask to form a pattern having a desired shape.

As the integration degree of the semiconductor device increases, the pattern of the semiconductor device may have a minute size, and a photolithography system using an extreme ultraviolet (EUV) light as a light source has been used. The photolithography system may have a high numerical aperture (NA) so as to increase the resolution, however, the mask 3-dimensional (3D) effect may also increase.

### SUMMARY

Example embodiments provide a photolithography method having improved characteristics.

Example embodiments provide a method of manufacturing a semiconductor device using a photolithography method having improved characteristics.

According to example embodiments, there is provided a photolithography method using a photolithography system including a light source, a photomask stage, a projection optical system and a wafer stage. The projection optical system may include an anamorphic lens. In the method, a wafer and a photomask may be mounted on the wafer stage and the photomask stage, respectively, and a first exposure process may be performed using the photomask to transfer layouts of patterns included in the photomask to a first half field of the wafer. A relative position of the photomask with respect to the wafer may be changed, and a second exposure process may be performed to transfer the layouts of the patterns included in the photomask to a second half field of the wafer.

According to example embodiments, there is provided a photolithography method using a photolithography system including a light source, a photomask stage, a projection optical system and a wafer stage. Horizontal directions substantially parallel to an upper surface or a lower surface of the photomask stage may include x-direction and y-direction substantially perpendicular to each other. The projection optical system may include an anamorphic lens having a reduction rate in the y-direction twice a reduction rate in the x-direction. In the method, a wafer and a photomask may be mounted on the wafer stage and the photomask stage, respectively. A first exposure process may be performed using the photomask to transfer layouts of patterns included in the photomask to a first half field of the wafer. A relative position of the photomask with respect to the wafer may be changed. A second exposure process may be performed to transfer the layouts of the patterns included in the photomask to a second half field of the wafer adjacent to the first field in the y-direction thereof. The second exposure process may be performed using the same photomask without replacing the photomask.

According to example embodiments, there is provided a photolithography method using a photolithography system including a light source, a photomask stage, a projection optical system and a wafer stage, the projection optical system including an anamorphic lens. In the method, a wafer and a photomask may be mounted on the wafer stage and the photomask stage, respectively. A first exposure process may be performed using the photomask to transfer layouts of patterns included in the photomask to a first half field of the wafer. A relative position of the photomask with respect to the wafer may be changed. A second exposure process may be performed to transfer the layouts of the patterns included in the photomask to a second half field of the wafer. The layouts of the patterns transferred to the first half field of the wafer and the layouts of the patterns transferred to the second half field of the wafer, except for a boundary between the first and second half fields of the wafer, may be substantially the same as each other.

According to example embodiments, there is provided a method of manufacturing a semiconductor device. In the method, a wafer and a photomask may be mounted on a wafer stage and a photomask stage, respectively, of a photolithography system. A first exposure process may be performed using the photomask to transfer layouts of patterns included in the photomask to a portion of a photoresist layer on a first half field of the wafer. The photolithography system may include a light source, the photomask stage, a projection optical system and the wafer stage, and the projection optical system may include an anamorphic lens. The wafer may include an etching object layer and the photoresist layer sequentially stacked thereon. A relative position of the photomask with respect to the wafer may be changed. A second exposure process may be performed to transfer the layouts of the patterns included in the photomask to a portion of a photoresist layer on a second half field of the wafer. A developing process may be performed on the photoresist layer to form a photoresist pattern. An etching process may be performed using the photoresist pattern as an etching mask to etch the etching object layer so that a material pattern is formed on the wafer.

According to example embodiments, there is provided a method of manufacturing a semiconductor device. In the method, a wafer and a photomask may be mounted on a wafer stage and a photomask stage, respectively, of a photolithography system. A first exposure process may be performed using the photomask to transfer layouts of patterns included in the photomask to a portion of a photoresist layer on a first half field of the wafer. Horizontal directions substantially parallel to an upper surface or a lower surface of the photomask stage may include x-direction and y-direction substantially perpendicular to each other. The photolithography system may include a light source, the photomask stage, a projection optical system and the wafer stage, and the projection optical system may include an anamorphic lens having a reduction rate in the y-direction twice a reduction rate in the x-direction. The wafer may include an etching object layer and the photoresist layer sequentially stacked thereon. A relative position of the photomask with respect to the wafer may be changed. A second exposure process may be performed to transfer the layouts of the patterns included in the photomask to a portion of the photoresist layer on a second half field of the wafer adjacent to the first field in the y-direction thereof. The second exposure process may be performed using the same photomask without replacing the photomask. A developing process may be performed on the photoresist layer to form a photoresist pattern. An etching process may be performed using the photoresist pattern as an etching mask to etch the etching object layer so that a material pattern is formed on the wafer.

According to example embodiments, there is provided a method of manufacturing a semiconductor device. In the method, a wafer and a photomask may be mounted on a wafer stage and a photomask stage, respectively, of a photolithography system. A first exposure process may be performed using the photomask to transfer layouts of patterns included in the photomask to a portion of a photoresist layer on a first half field of the wafer. The photolithography system may include a light source, the photomask stage, a projection optical system and the wafer stage, and the projection optical system may include an anamorphic lens. The wafer may include an etching object layer and the photoresist layer sequentially stacked thereon. A relative position of the photomask with respect to the wafer may be changed. A second exposure process may be performed to transfer the layouts of the patterns included in the photomask to a portion of a photoresist layer on a second half field of the wafer. A developing process may be performed on the photoresist layer to form a photoresist pattern. An etching process may be performed using the photoresist pattern as an etching mask to etch the etching object layer so that a material pattern is formed on the wafer. The layouts of the patterns transferred to the first half field of the wafer and the layouts of the patterns transferred to the second half field of the wafer, except for a boundary between the first and second half fields of the wafer, may be substantially the same as each other.

In the photolithography method, two exposure processes covering first and second half fields of the wafer do not need to be performed using different photomasks, but may be performed using the same photomask. Thus, the time for replacing the photomask is not needed, so as to decrease the process time.

### BRIEF DESCRIPTION OF THE DRAWINGS

Features will become apparent to those of skill in the art by describing in detail exemplary embodiments with reference to the attached drawings in which:

FIG. 1 is a schematic cross-sectional view illustrating a photolithography system in accordance with example embodiments.

FIGS. 2 and 3 are plan views illustrating photomasks and areas of a wafer onto which lights reflected from the photomasks are incident in exposure processes using the photomasks, respectively.

FIG. 4 is a plan view illustrating a layout of a pattern included in the third photomask M3 in example embodiments.

FIG. 5 is a plan view illustrating a layout of a pattern transferred to the field of the wafer WF by the third and fourth exposure processes using the third photomask M3.

FIG. 6 is a plan view illustrating layouts of patterns transferred to the first and second half fields H1 and H2 of the wafer WF by the third and fourth exposure processes using the third photomask M3.

FIG. 7 is a plan view illustrating the third photomask M3 in example embodiments.

FIG. 8 is a plan view illustrating layouts of patterns transferred to the first and second half fields H1 and H2 of the wafer WF by the third and fourth exposure processes using the third photomask M3.

FIG. 9 is a plan view illustrating the third photomask M3 in example embodiments.

FIG. 10 is a plan view illustrating layouts of patterns transferred to the first and second half fields H1 and H2 of the wafer WF by the third and fourth exposure processes using the third photomask M3.

FIG. 11 is a plan view illustrating the third photomask M3 in example embodiments.

FIGS. 12 and 13 are plan views illustrating layouts of patterns transferred to the first and second half fields H1 and H2 of the wafer WF by the third and fourth exposure processes using the third photomask M3.

FIGS. 14 to 51 are plan views and cross-sectional views illustrating a method of manufacturing a semiconductor device according to example embodiments.

### DETAILED DESCRIPTION

The above and other aspects and features of a semiconductor device and a method of forming the same in accordance with example embodiments will become readily understood from detail descriptions that follow, with reference to the accompanying drawings. It will be understood that, although the terms “first,” “second,” and/or “third” may be used herein to describe various materials, layers (films), regions, electrodes, pads, patterns, structures and processes, these materials, layers (films), regions, electrodes, pads, patterns, structures and processes should not be limited by these terms. These terms are only used to distinguish one material, layer (film), region, electrode, pad, pattern, structure and process from another material, layer (film), region, electrode, pad, pattern, structure and process. Thus, a first material, layer (film), region, electrode, pad, pattern, structure and process discussed below could be termed a second or third material, layer (film), region, electrode, pad, pattern, structure and process without departing from the teachings thereof.

Patterns on a wafer may be formed by forming an etching object layer on the wafer, forming a photoresist layer on the etching object layer, patterning the photoresist layer to form a photoresist pattern, and etching the etching object layer using the photoresist pattern as an etching mask. An etching mask layer may be further formed between the etching object layer and the photoresist layer. In this case, the etching mask layer may be etched using the photoresist pattern to form an etching mask, and the etching object layer may be etched using the etching mask.

The formation of the photoresist pattern by patterning the photoresist layer may be performed by placing a photomask, e.g., a reticle including a given pattern over the photoresist layer, performing an exposure process in which a light is emitted from a light source to penetrate through the photomask, and performing a developing process in which a portion of the photoresist layer exposed or unexposed by the light is removed, so that a layout of the given pattern may be transferred to the photoresist layer.

A photolithography process for forming a pattern having a desired shape on a wafer using a photomask and a photoresist pattern may be performed by a photolithography system, as follows.

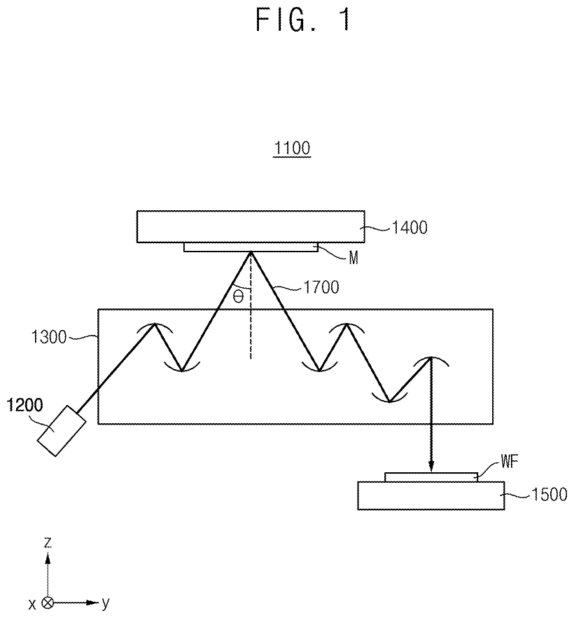

FIG. 1 is a schematic cross-sectional view illustrating a photolithography system in accordance with example embodiments.

Referring to FIG. 1, a photolithography system 100 may include a light emitting part 1200, an optical system 1300, a mask stage 1400 and a wafer stage 1500.

In example embodiments, the photolithography system 100 may perform a lithography process using a light 1700 and a photomask M.

In particular, the light emitting part 1200 may include, e.g., a light source, a light collector, etc. The light source may generate using, e.g., a plasma source, a laser induced source, an electric charge gas plasma source, etc. In an example embodiment, the light 1700 may be an extreme ultraviolet (EUV) light having a wavelength of about 13.5 nm. In some implementations, the light 1700 may be a deep ultraviolet (DUV) light having a wavelength of about 193 nm. The light 1700 may pass through the light collector to be incident into the optical system 1300.

The optical system 1300 may include, e.g., mirrors, lenses, etc. In example embodiments, the optical system 1300 may include an illumination optical system and a projection optical system.

The illumination optical system may include optical elements e.g., illumination mirrors and/or illumination lenses in order to induce the light 1700 generated by the light source toward the photomask M that is installed on a lower surface of the mask stage 1400.

The mask stage 1400 may move in a horizontal direction substantially parallel to an upper surface or a lower surface of the mask stage 1400 with the photomask M thereon. The horizontal direction may include two directions, e.g., an x-direction and a y-direction. The mask stage 1400 may move in the x-direction or in the y-direction. A vertical direction substantially perpendicular to the upper surface or the lower surface of the mask stage 1400 may be referred to as a z-direction.

The mask stage 1400 may further include an electrostatic chuck for fixing the photomask M.

The light 1700 induced onto the photomask M installed at the mask stage 1400 may be incident into the lower surface of the photomask M with an incident angle θ. The light 1700 may be reflected onto the projection optical system. The projection optical system may include optical elements, e.g., projection mirrors and/or projection lenses in order to induce the light 1700 reflected from the photomask M to move toward a wafer WF mounted on the wafer stage 1500.

The wafer stage 1500 may move in the horizontal direction with the wafer WF thereon. For example, a photoresist layer having a given thickness may be formed on the wafer WF. A focus of the light 1700 induced toward the wafer WF mounted on the wafer stage 1500 may be located within the photoresist layer.

Thus, the light 1700 generated from the light source may be reflected onto the photomask M to be illuminated on the photoresist layer on the wafer WF by an exposing process The photoresist layer may be patterned based on optical pattern information of the reflective photoresist M by a developing process to be transformed into a photoresist pattern. An etching object layer under the photoresist pattern may be patterned based on the photoresist pattern so that a pattern may be formed on the wafer WF.

The photomask M may include a multi-layered structure, a capping layer and an absorber sequentially stacked on a substrate.

The substrate may include a low thermal expansion material, e.g., quartz glass, silicon, silicon carbide, etc. In an example embodiment, the substrate may include quartz glass doped with titanium oxide.

The multi-layered structure may include a first layer and a second layer alternately and repeatedly stacked in a vertical direction substantially perpendicular to an upper surface of the substrate. In example embodiments, the first and second layers may include molybdenum and silicon, respectively. In some embodiments, the first and second layers may include molybdenum and beryllium, respectively. The multi-layered structure may include the first and second layers having different refractive indexes and alternately stacked in the vertical direction, and may reflect the light 1700 incident on the multi-layered structure.

The capping layer may be formed on an upper surface of the multi-layered structure, and may protect the capping layer. In an example embodiment, the capping layer may include ruthenium.

The absorber may include a material that can absorb the light 1700. For example, the absorber may be or include tantalum, a tantalum compound, etc. In example embodiments, the absorber may include tantalum nitride or tantalum boronitride. In some implementations, the absorber may include, e.g., molybdenum, palladium, zirconium, nickel silicide, titanium, titanium nitride, chrome, chrome oxide, aluminum oxide, aluminum copper alloy, etc. The absorber may have a shape of a pillar extending in the vertical direction.

The light 1700 may be incident onto the photomask M at an angle slanted with respect to an upper surface of the photomask M with a slope angel θ. Some of the light 1700 incident onto a first area where the absorber is formed may be absorbed by the absorber. Some of the light incident on a second area where the absorber is not formed may penetrate through the capping layer to be reflected from an effective reflection surface of the multi-layered structure and to move to the projection optical system of the optical system 1300.

When the light 1700 incident on the upper surface of the photomask M is slanted, some of the light 1700 incident even on a third area near the first area may be absorbed by the absorber so as to not to be reflected, and thus the mask 3D effect could occur.

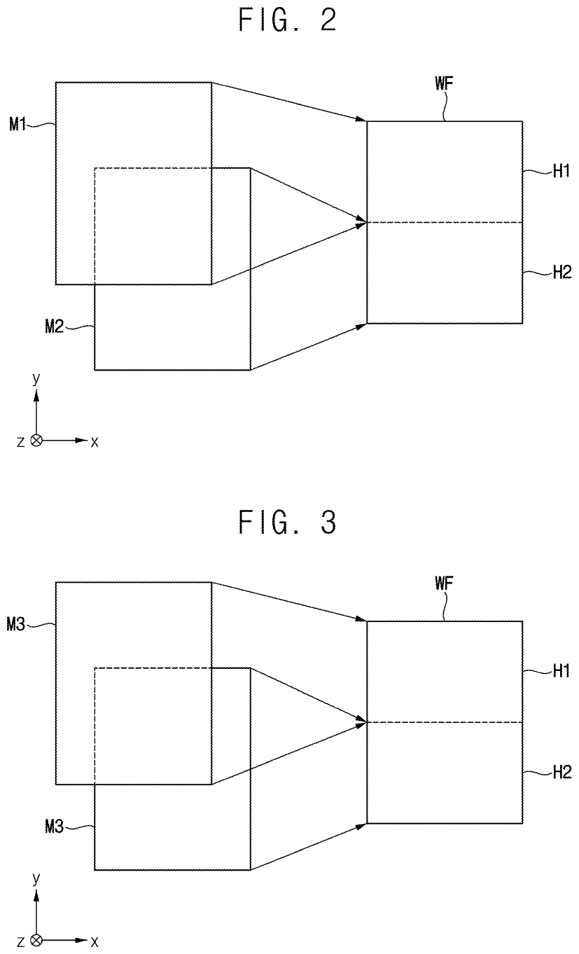

FIGS. 2 and 3 are plan views illustrating photomasks, and areas of a wafer onto which light reflected from the photomasks are incident in exposure processes using the photomasks, respectively.

Referring to FIGS. 1 and 2, in an exposure process using a photomask in a comparative embodiment, the light 1700 generated at the light emitting part 1200 may be induced onto a first photomask M1 on a lower surface of the mask stage 1400 by the illumination optical system included in the optical system 1300 to be incident on a lower surface of the first photomask M1 with a slope angle θ. T light 1700 reflected from the lower surface of the first photomask M1 may be induced into the wafer W mounted on the wafer stage 1500 by the projection optical system included in the optical system 1300 to be incident on an upper surface of the wafer W.

An area of the light 1700 incident on the upper surface of the wafer W may decrease by a given ratio, that is, a reduction rate when compared to an area of the light 1700 incident on the lower surface of the first photomask M1. That is, the projection optical system may have a given reduction rate. However, the optical system may be an anamorphic system including an anamorphic lens having different reduction rates in the x-direction and the y-direction. For example, the projection optical system may have a reduction rate of 4:1 in the x-direction and a reduction rate of 8:1 in the y-direction.

Thus, when a first exposure process is performed using the first photomask M1, a layout of a pattern included in the first photomask M1 may be transferred to a first half field H1 that may correspond to half a region, that is, to a field to which the layout of the pattern included in the first photomask M1 is transferred by a projection system having the same reduction rate in the x-direction and the y-direction.

The first photomask M1 on the mask stage 1400 may be replaced with a second photomask M2 having the same size as the first photomask M1. The mask stage 1400 or the wafer stage 1500 may be moved in the y-direction, and a second exposure process may be performed using the second photomask M2, such that a layout of a pattern included in the second photomask M2 may be transferred to a second half field H2, which may correspond to half of the field. The second half of the field H2 may be adjacent to the first half of the field H1 in the y-direction.

In the comparative embodiment, the projection optical system included in the photolithography system 1100 may have a reduction rate in the x-direction, e.g., 4:1 that is greater than a reduction rate in the y-direction, e.g., 8:1. The photolithography system 1100 may have a high NA, e.g., 0.55 of the photomask M, and thus a critical dimension (CD) of a pattern formed on the wafer WF by the photolithography system 1100 may decrease so as to increase the resolution.

However, when the NA of the photomask M has a high value, the slope angle θ of a light incident on the photomask M may increase such that the mask 3D effect may intensify, and such that a light incident on the photomask M and a light reflected from the photomask M may partially overlap each other. Thus, the projection optical system may have a reduction rate in the y-direction that is greater than a reduction rate in the x-direction in order to decrease the slope angle θ of the light incident on the photomask M.

When the reduction rate in the x-direction is different from the reduction rate in the y-direction in the projection optical system, only a portion of the field that may be covered in a single exposure process using a photomask. For example, when the exposure process is performed with one shot using a projection optical system having the same reduction rate in the x-direction and in the y-direction a plurality of exposure processes may be performed to cover the field entirely.

In the comparative embodiment, if the reduction rate in the y-direction is twice the reduction rate in the x-direction, the first and second exposure processes may be performed using two different photomasks, that is, the first and second photomasks M1 and M2. Accordingly, there needs to be time for replacing the first and second photomasks M1 and M2 from the mask stage 1400.

Referring to FIGS. 1 and 3, in an exposure process using a photomask in example embodiments, a third exposure process may be performed using a third photomask M3, and thus a layout of a pattern included in the third photomask M3 may be transferred to the first half field H1 of the wafer WF.

Without replacing the third photomask M3 on the mask stage 1400, for example, the mask stage 1400 or the wafer stage 1500 may be moved in the y-direction, and a fourth exposure process may be performed using the same third photomask M3, such that the layout of the pattern included in the third photomask M3 may be transferred to the second half field H2 of the wafer WF.

That is, in example embodiments, the third and fourth exposure processes may be performed without using different photomasks, but using the same photomask, that is, the third photomask M3. Accordingly, time for replacing the photomasks from the mask stage 1400 is not needed.

In example embodiments, the third photomask M3 used in each of the third and fourth exposure processes may include all patterns included in each of the first and second photomasks M1 and M2. Hereinafter, the patterns included in the third photomask M3 is described.

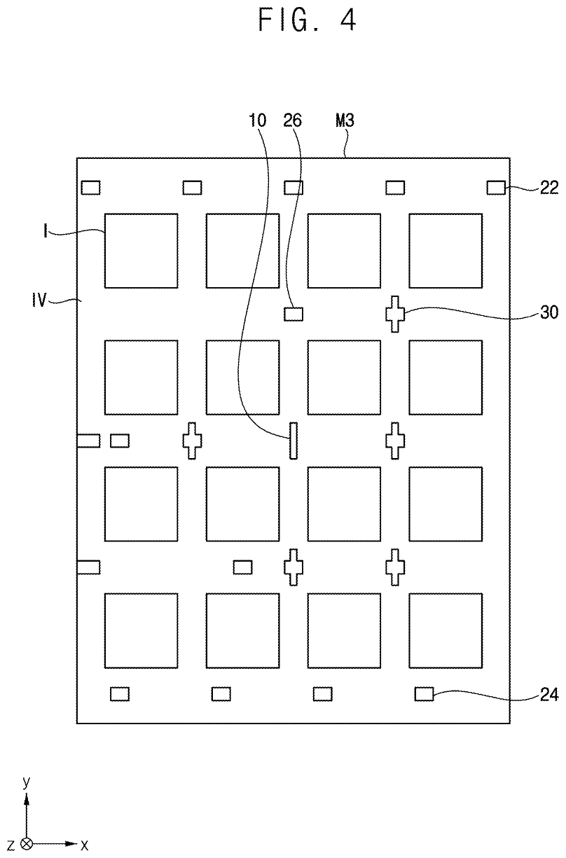

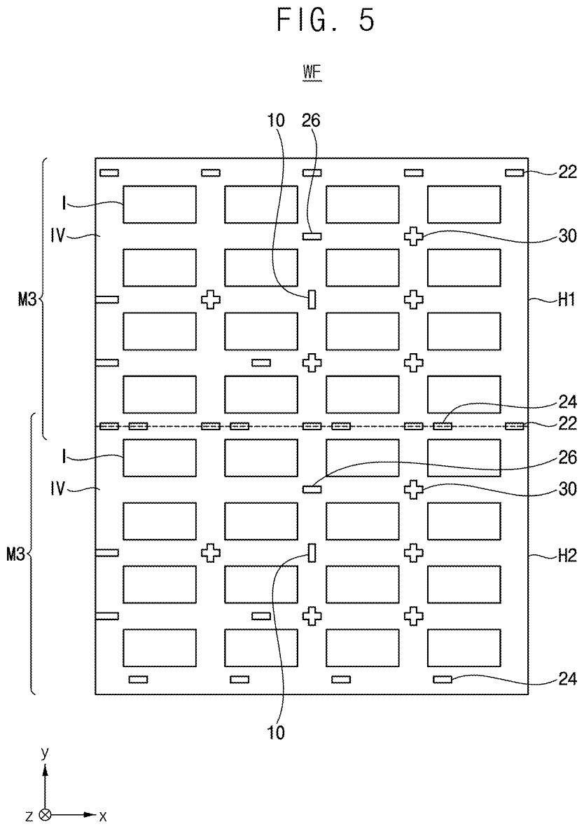

FIG. 4 is a plan view illustrating a layout of a pattern included in the third photomask M3 in example embodiments. FIG. 5 is a plan view illustrating a layout of a pattern transferred to the field of the wafer WF by the third and fourth exposure processes using the third photomask M3.

Referring to FIG. 4, the third photomask M3 may include a first region I and a fourth region IV.

In example embodiments, the first region I may be a chip region including patterns of a semiconductor chip, and the fourth region IV may be a scribe lane region including keys or marks.

In example embodiments, a plurality of first regions I may be arranged in the x-direction and the y-direction. The fourth region IV may surround the first regions I.

The third photomask M3 may include an alignment key or alignment mark, an overlay key or an overlay mark, and a test element group (TEG) in the fourth region IV.

The alignment key may be used in aligning a photomask used in an exposure process over a wafer The overlay key may be used in detecting an overlay between a material pattern on the wafer and the photoresist pattern on the material pattern and correcting the misalignment. However, in some cases, each of the alignment key and the overlay key may have both of the above meanings. The TEG may be a structure used in testing electric characteristics and failure of various elements included in the semiconductor chip on the chip region of the wafer.

In example embodiments, a first alignment key 10, first, second and third overlay keys 22, 24 and 26, and a TEG 30 may be formed in the fourth region IV. Each of the first alignment key 10, the first, second and third overlay keys 22, 24 and 26, and the TEG 30 may have various shapes and various layouts in the fourth region IV.

FIG. 4 shows that the first alignment key 10 has a shape of a rectangle with a length in the y-direction greater than a length in the x-direction, each of the first to third overlay keys 22, 24 and 26 may have a shape of a rectangle with a length in the x-direction greater than a length in the y-direction. The TEG 30 may have a shape of a cross in a plan view, as non-limiting examples.

In an example embodiment, the first alignment key 10 may be formed in a portion of the fourth region IV at a central portion of the third photomask M3, as non-limiting examples.

The first overlay key 22 may be formed in a portion of the fourth region IV at an upper end portion in the y-direction of the third photomask M3, the second overlay key 24 may be formed in a portion of the fourth region IV at a lower end in the y-direction of the third photomask M3. The third overlay key 26 may be formed in a portion of the fourth region IV at a central portion in the y-direction of the third photomask M3.

Referring to FIG. 5, the third and fourth exposure processes may be performed using the third photomask M3 so that layouts of the patterns included in the third photomask M3 may be transferred to the field of the wafer WF, that is, to each of the first and second half fields H1 and H2.

When a photoresist layer is formed on the wafer WF, the layouts of the patterns included in the third photomask M3 may be transferred to the photoresist layer.

As in the comparative embodiment, the projection optical system of the photolithography system 1100 used in the third and fourth exposure processes using the third photomask M3 in example embodiments may have a reduction rate in the y-direction greater than a reduction rate in the x-direction. Thus, the layout of the patterns included in the third photomask M3 could be transferred to the first half field H1 by the third exposure process, and the layout of the patterns included in the third photomask M3 could be transferred to the second half field H2 by the fourth exposure process.

However, in example embodiments, the layout of the patterns transferred to the wafer WF by the third exposure process and the layout of the patterns transferred to the wafer WF by the fourth exposure process may partially overlap each other.

That is, the layout of the pattern disposed in the portion of the fourth region IV at the lower end portion in the y-direction of the third photomask M and the layout of the pattern disposed in the portion of the fourth region IV at the upper end portion in the y-direction of the third photomask M might be transferred by the third and fourth exposure processes onto the wafer WF so as to overlap each other. Thus, FIG. 5 shows that the layout of the second overlay key 24 transferred to the wafer WF by the third exposure process and the layout of the first overlay key 22 transferred to the wafer WF by the fourth exposure process are arranged side by side in the x-direction in a portion of the fourth region IV at a boundary between the first and second half fields H1 and H2.

In example embodiments, the third and fourth exposure processes may not be performed using the different photomasks, that is, the first and second photomasks M1 and M2, but may be performed using the same photomask, that is, the third photomask M3, such that the time for replacing photomasks may be saved.

The first and second photomasks M1 and M2 in the comparative embodiment may have different patterns from each other, while the third photomask M3 in example embodiments may have all the patterns included in the first and second photomasks M1 and M2. Generally, semiconductor chips may include the same patterns at the same positions on respective chip regions of a wafer, while the semiconductor chips may include different patterns, e.g., alignment keys, overlay keys and TEGs at the same positions on respective scribe lane regions of the wafer.

Thus, in the comparative embodiment, the patterns in the first region I of the first photomask M1 may be substantially the same as the patterns in the first region I of the second photomask M2, while the alignment keys, the overlay keys and the TEGs in the fourth region IV of the first photomask M1 may be different from the alignment keys, the overlay keys and the TEGs in the fourth region IV of the second photomask M2.

In example embodiments, the third photomask M3 may include all of the alignment keys in the fourth region IV., the overlay keys and the TEGs in each of the first and second photomasks M1 and M2, such that the third and fourth exposure processes need not be performed using the different photomasks.

When the third and fourth exposure processes are performed using the same third photomask M3, the layouts of the patterns transferred to the first and second half fields H1 and H2 by the third and fourth exposure processes, respectively, may be substantially the same as each other.

As illustrated above, when the first and second exposure processes are performed according to the comparative embodiment, the different patterns may be formed in the fourth regions IV of the first and second photomasks M1 and M2, respectively. Thus, the layouts of the different patterns may be transferred to the first and second half fields H1 and H2, respectively. However, in example embodiments, the layouts of the same patterns may be transferred to the first and second half fields H1 and H2 neighboring in the y-direction. Both of the layout of the pattern at the upper end portion in the y-direction of the third photomask M3 and the layout of the pattern at the lower end portion in the y-direction of the third photomask M3 could be transferred to the boundary between the first and second half fields H1 and H2 of the wafer WF.

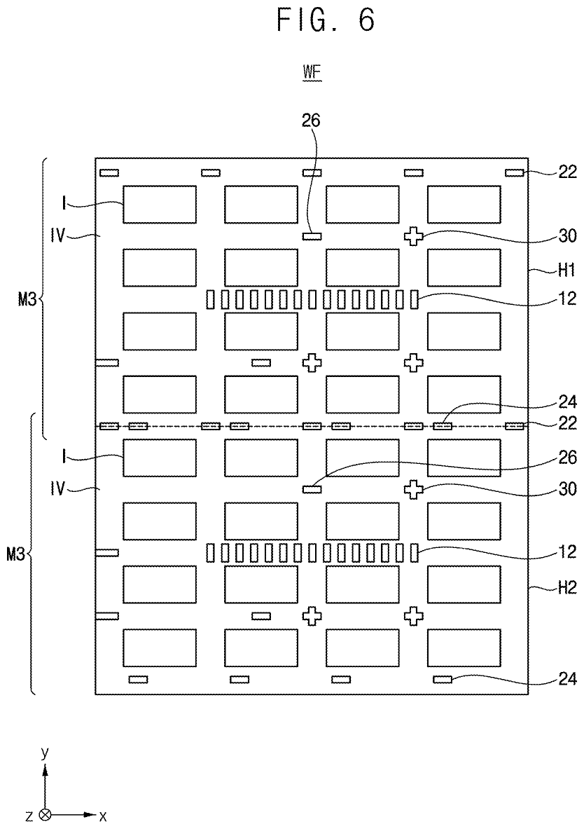

FIG. 6 is a plan view illustrating layouts of patterns transferred to the first and second half fields H1 and H2 of the wafer WF by the third and fourth exposure processes using the third photomask M3.

The third photomask M3 and the layouts of the patterns transferred to the wafer WF using the third photomask M3 shown in FIG. 6 may be substantially the same as those of FIGS. 4 and 5, except for including the second alignment key 12 instead of the first alignment key 10, and thus repeated explanations are not repeated herein.

Referring to FIG. 6, the second alignment key 12 may be formed in the portion of the fourth region IV at the central portion in the y-direction of the third photomask M3.

In example embodiments, a plurality of second alignment keys 12 may be spaced apart from each other in the x-direction in the portion of the fourth region IV.

Thus, layouts of the second alignment keys 12 may be transferred to the portion of the fourth region IV at the central portion in the y-direction of each of the first and second half fields H1 and H2 of the wafer WF.

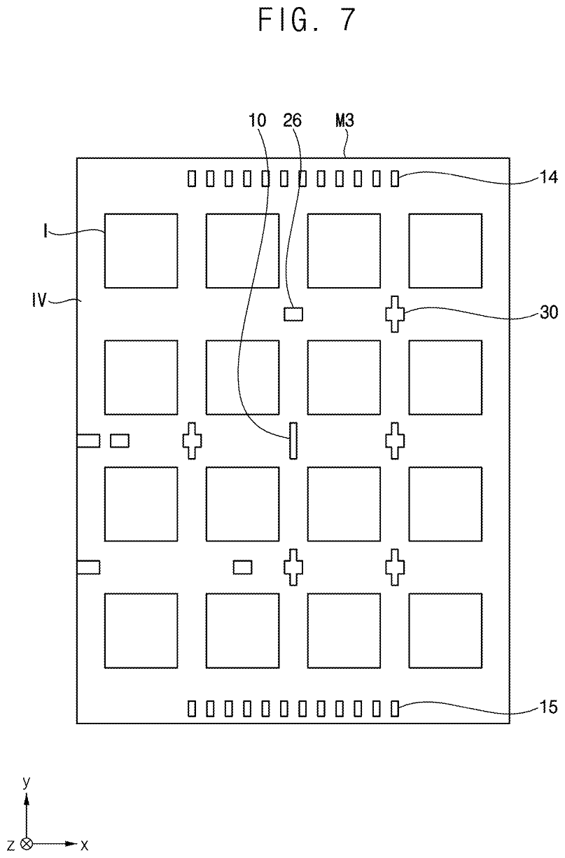

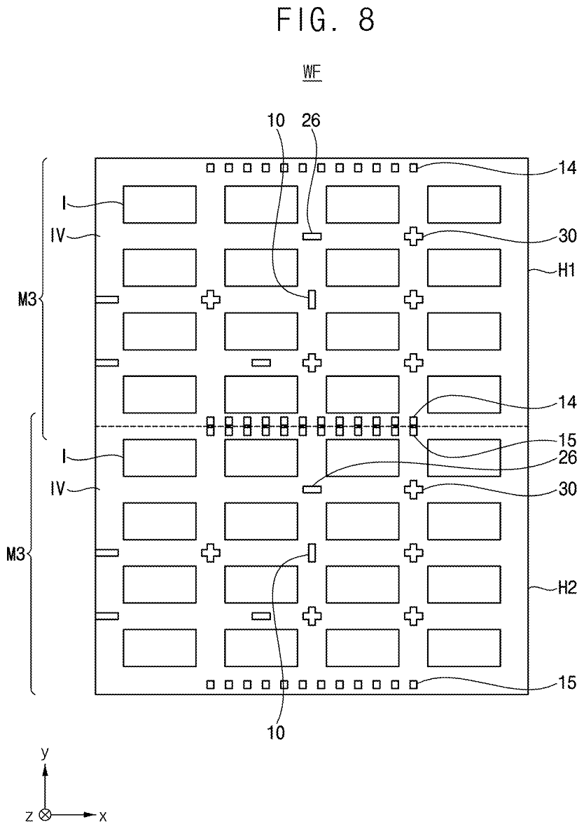

FIG. 7 is a plan view illustrating the third photomask M3 in example embodiments. FIG. 8 is a plan view illustrating layouts of patterns transferred to the first and second half fields H1 and H2 of the wafer WF by the third and fourth exposure processes using the third photomask M3.

The third photomask M3 in FIG. 7 and the layouts of the patterns transferred to the wafer WF using the third photomask M3 in FIG. 8 are substantially the same as those of FIGS. 4 and 5, except for including the third and fourth alignment keys 14 and 15 instead of the first and second overlay keys 22 and 24, and thus repeated explanations are not repeated herein.

Referring to FIG. 7, a plurality of third alignment keys 14 may be spaced apart from each other in the x-direction in the portion of the fourth region IV at the upper end portion in the y-direction of the third photomask M3 A plurality of fourth alignment keys 15 may be spaced apart from each other in the x-direction in the portion of the fourth region IV at the lower end portion in the y-direction of the third photomask M3.

In example embodiments, the fourth alignment keys 15 may overlap the third alignment keys 14 in the y-direction. Additionally, the third alignment keys 14 may be formed at an upper portion in the y-direction of the portion of the fourth region IV at the upper end portion in the y-direction of the third photomask M3. The fourth alignment keys 15 may be formed at a lower portion in the y-direction of the portion of the fourth region IV at the lower end portion in the y-direction of the third photomask M3.

Referring to FIG. 8, both of the layout of the third alignment key 14 at the upper end portion in the y-direction of the third photomask M3 and the layout of the fourth alignment key 15 at the lower end portion in the y-direction of the third photomask M3 may be transferred to the boundary between the first and second half fields H1 and H2 of the wafer WF.

Thus, stitches each of which may include the third alignment key 14 and the fourth alignment key 15 neighboring in the y-direction may be formed at the boundary between the first and second half fields H1 and H2.

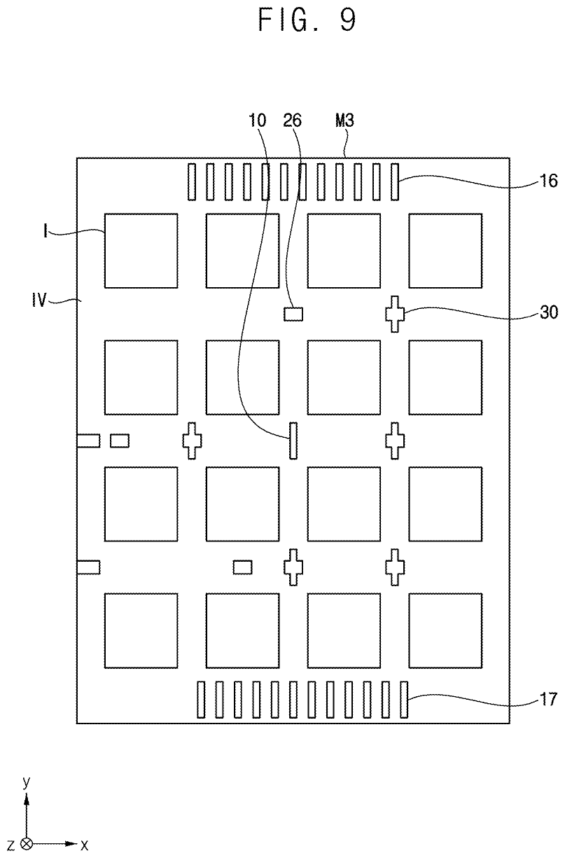

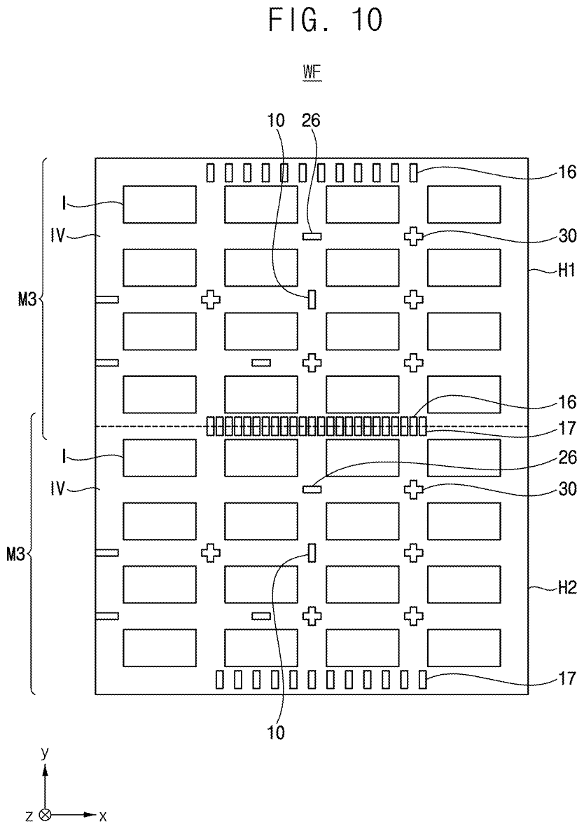

FIG. 9 is a plan view illustrating the third photomask M3 in example embodiments FIG. 10 is a plan view illustrating layouts of patterns transferred to the first and second half fields H1 and H2 of the wafer WF by the third and fourth exposure processes using the third photomask M3.

The third photomask M3 in FIG. 9 and the layouts of the patterns transferred to the wafer WF using the third photomask M3 in FIG. 10 are substantially the same as those of FIGS. 7 and 8, except for including the fifth and sixth alignment keys 16 and 17 instead of the third and fourth alignment keys 14 and 15, and thus repeated explanations are not repeated herein.

Referring to FIG. 9, a plurality of fifth alignment keys 16 may be spaced apart from each other in the x-direction in the portion of the fourth region IV at the upper end portion in the y-direction of the third photomask M3 A plurality of sixth alignment keys 17 may be spaced apart from each other in the x-direction in the portion of the fourth region IV at the lower end portion in the y-direction of the third photomask M3.

In example embodiments, the sixth alignment keys 17 may not overlap in the y-direction the fifth alignment keys 16, but may overlap in the y-direction an area between neighboring ones of the fifth alignment keys 16 in the x-direction. Additionally, a length in the y-direction of the sixth alignment key 17 may be substantially the same as a length in they y-direction of the fifth alignment keys 16, as non-limiting examples.

Referring to FIG. 10, both of the layout of the fifth alignment key 16 at the upper end portion in the y-direction of the third photomask M3 and the layout of the sixth alignment key 17 at the lower end portion in the y-direction of the third photomask M3 may be transferred to the boundary between the first and second half fields H1 and H2 of the wafer WF.

Thus, a zipper including the fifth and sixth alignment keys 16 and 17 alternately and repeatedly disposed in the x-direction may be formed at the boundary between the first and second half fields H1 and H2.

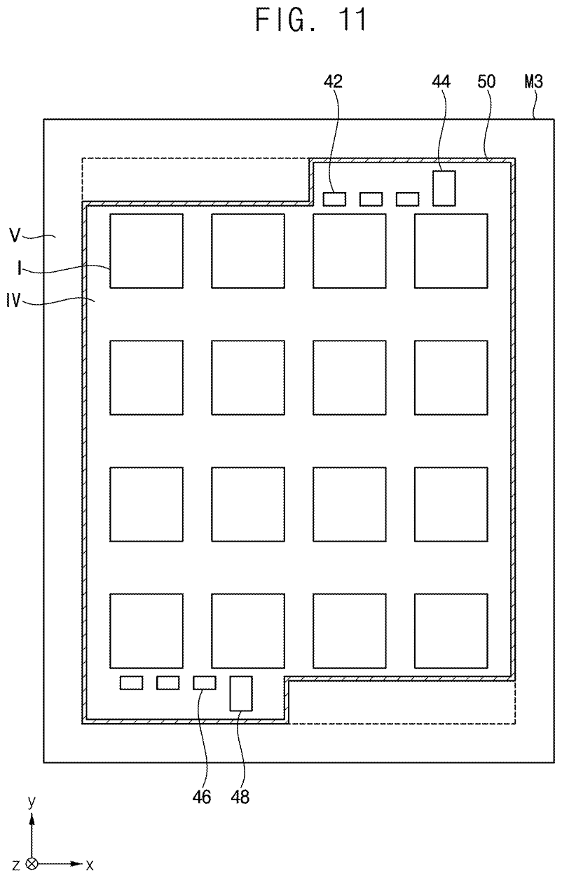

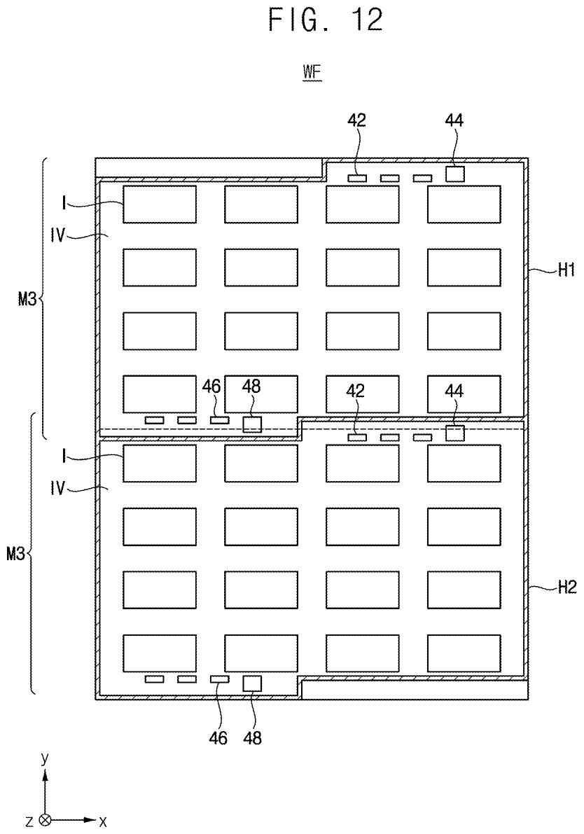

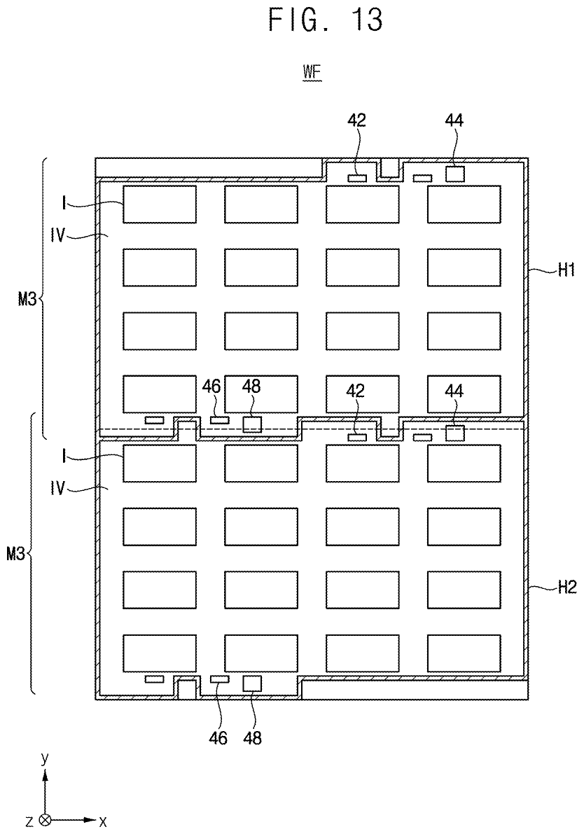

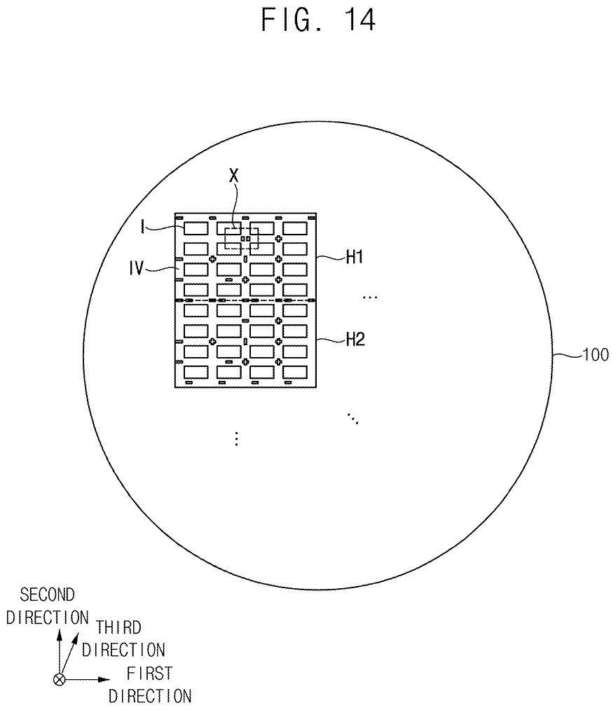

FIG. 11 is a plan view illustrating the third photomask M3 in example embodiments. FIGS. 12 and 13 are plan views illustrating layouts of patterns transferred to the first and second half fields H1 and H2 of the wafer WF by the third and fourth exposure processes using the third photomask M3.

The third photomask M3 in FIG. 11 and the layouts of the patterns transferred to the wafer WF using the third photomask M3 in FIGS. 12 and 13 are substantially the same as those of FIGS. 3 and 4, except for including the fourth to seventh overlay keys 42, 44, 46 and 48 instead of the first and second overlay keys 22 and 24, and further including a fifth region V and a restriction region 50, and thus repeated explanations are not repeated herein.

Referring to FIG. 11, the fourth and fifth overlay keys 42 and 44 may be formed in the portion of the fourth region IV at the upper end portion in the y-direction of the third photomask M3 The sixth and seventh overlay keys 46 and 48 may be formed in the portion of the fourth region IV at the lower end portion in the y-direction of the third photomask M3.

A length in the y-direction of the fifth overlay key 44 may be greater than a length in the y-direction of the fourth overlay key 42, and a length in the y-direction of the seventh overlay key 48 may be greater than a length in the y-direction of the sixth overlay key 46.

In example embodiments, the fifth region V may surround the fourth region IV. The fifth region V may include a portion of the fourth region IV.

The fifth region V may be an optical density (OD) region in which a multi-layered structure for reflecting light is not formed so that the light incident on the third photomask M3 does not reflect but penetrates, or the fifth region V may be an out of band (00B) region in which a light having a wavelength except for the wavelength of EUV light is scattered.

The restriction region 50 may be formed at a boundary between the fourth and fifth regions IV and V, and no patterns may be formed in the restriction region 50.

When the first and fourth regions I and IV has a shape of a rectangle and the fifth region V has a shape of a rectangular ring in a plan view, the restriction region 50 may also have a shape of a rectangular ring in a plan view.

In example embodiments, the restriction region 50 may also be formed in a portion of the fourth region IV in which no patterns are formed. In this case, the fifth region V may include a portion of the fourth region IV at an outside of the restriction region 50, that is, a left upper end portion and a right lower end portion in FIG. 11.

Thus, FIG. 11 shows that the restriction region 50 is formed at a boundary between the fourth and fifth regions IV and V near the fourth and fifth overlay keys 42 and 44, and is formed in an inside of the fourth region IV distal to the fourth and fifth overlay keys 42 and 44.

Additionally, FIG. 11 shows that the restriction region 50 is formed at the boundary between the fourth and fifth regions IV and V near the sixth and seventh overlay keys 46 and 48, and is formed in the inside of the fourth region IV distal to the sixth and seventh overlay keys 46 and 48.

Referring to FIG. 12, both of the layout of the fourth and fifth overlay keys 42 and 44 at the upper end portion in the y-direction of the third photomask M3 and the layout of the sixth and seventh overlay keys 46 and 48 at the lower end portion in the y-direction of the third photomask M3 may be transferred to the boundary between the first and second half fields H1 and H2 of the wafer WF.

A first portion of the restriction region 50 extending in the x-direction near the fourth and fifth overlay keys 42 and 44 and a second portion of the restriction region 50 extending in the x-direction near the sixth and seventh overlay keys 46 and 48 may not be in the line in the x-direction, but may be offset in the y-direction at the boundary between the first and second half fields H1 and H2 of the wafer WF, and the first and second portions of the restriction region 50 may be connected with each other by a third portion extending in the y-direction.

Referring to FIG. 13, unlike the restriction region 50 in FIG. 12, the restriction region 50 may include portions extending in the y-direction, which are not disposed in a central portion in the x-direction at the boundary between the first and second half fields H1 and H2, and the portions may be adjacent to the first region I of the third photomask M3 transferred to the first half field H1 of the wafer WF or the first region I of the third photomask M3 transferred to the second half field H2 of the wafer WF.

That is, the restriction region 50 may have a shape of a zigzag adjacent to contours of the patterns in the fourth region IV, instead of a bar shape extending in the x-direction, at the upper or lower end portion in the y-direction of each of the first and second half fields H1 and H2, or at the boundary between the first and second half fields H1 and H2.

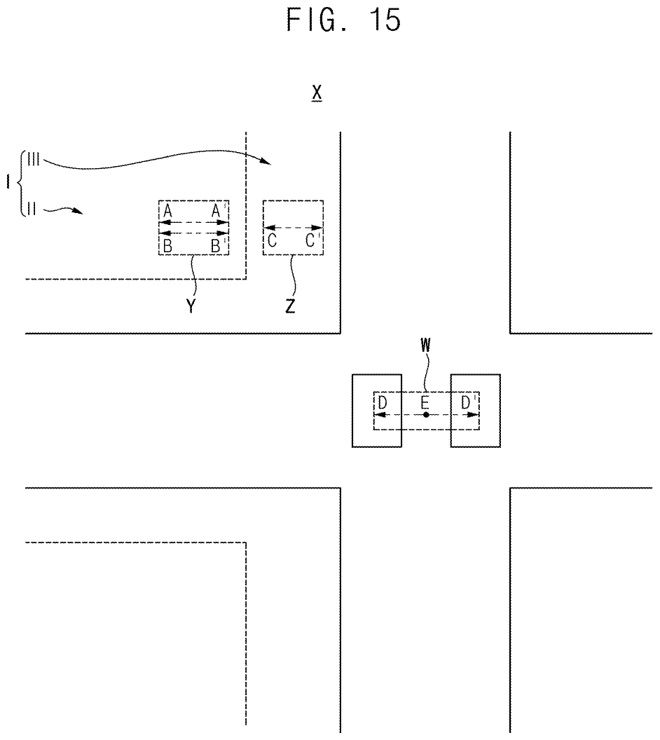

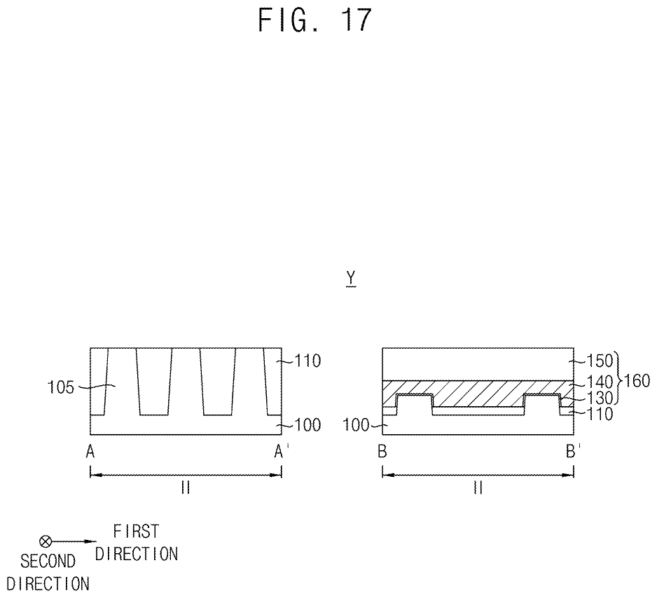

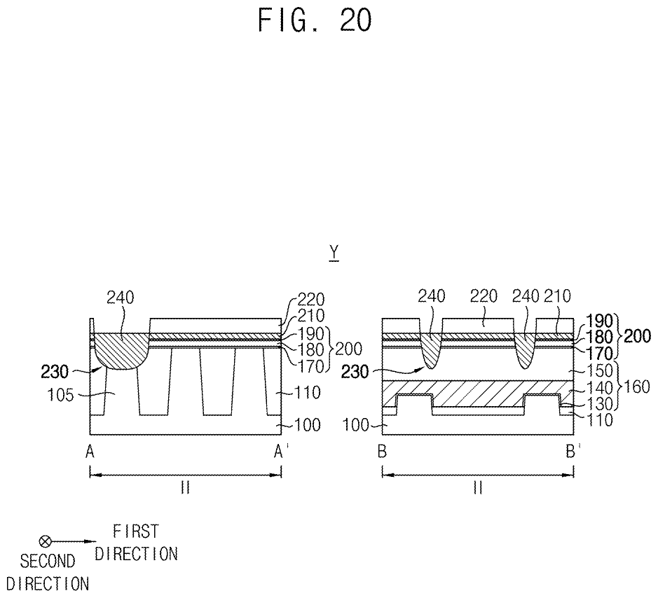

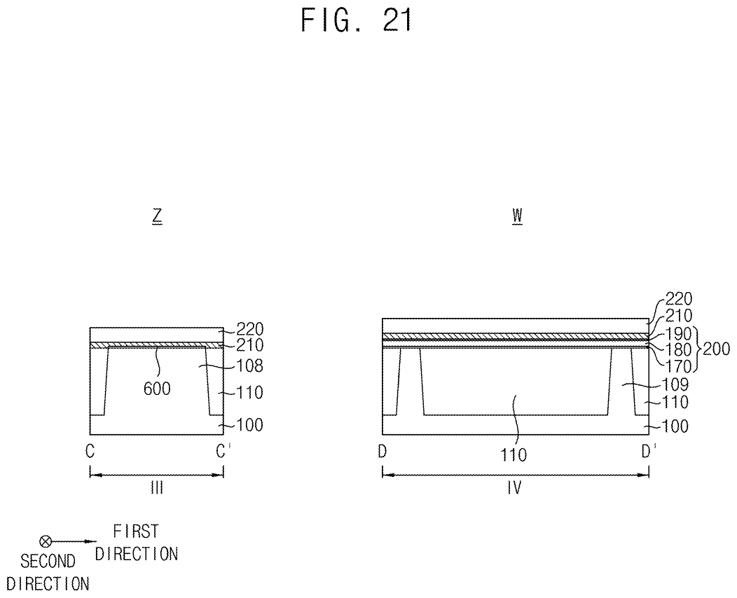

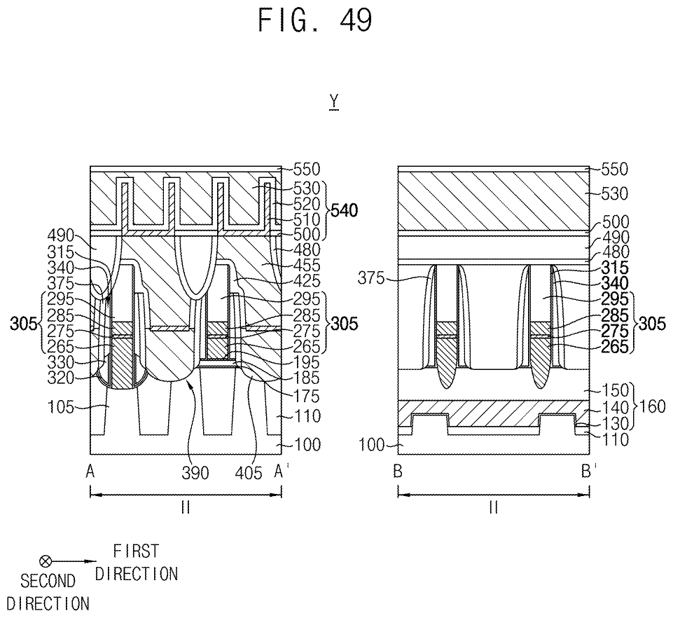

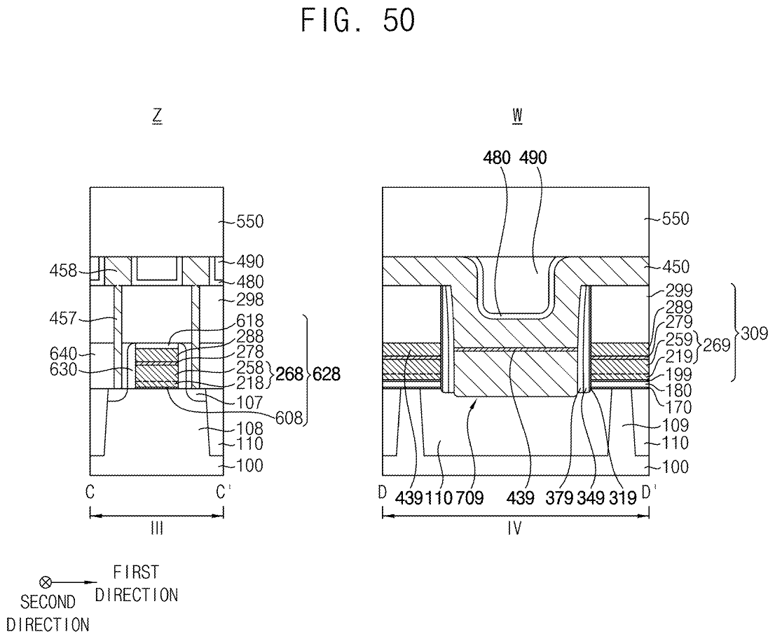

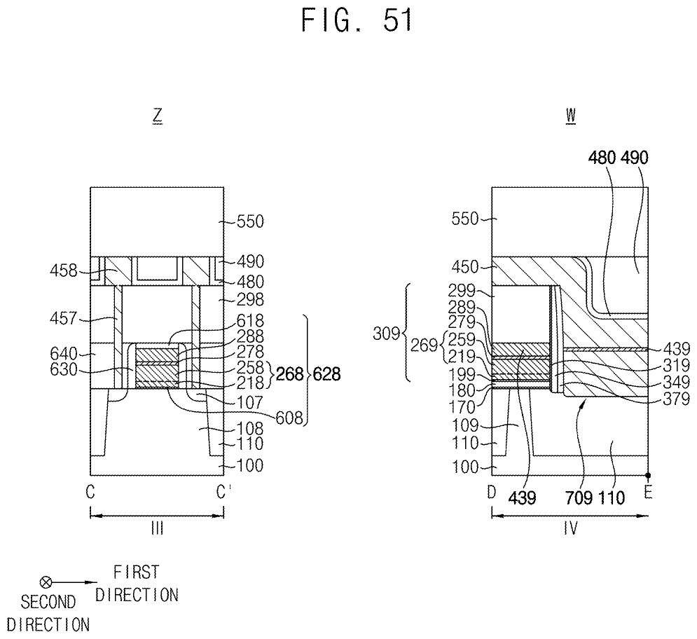

FIGS. 14 to 51 are plan views and cross-sectional views illustrating a method of manufacturing a semiconductor device according to example embodiments. Specifically, FIGS. 14-16, 19, 24, 35 and 48 are the plan views, and FIGS. 17-18, 20-23, 25-34, 36-47 and 39-51 are the cross-sectional views.

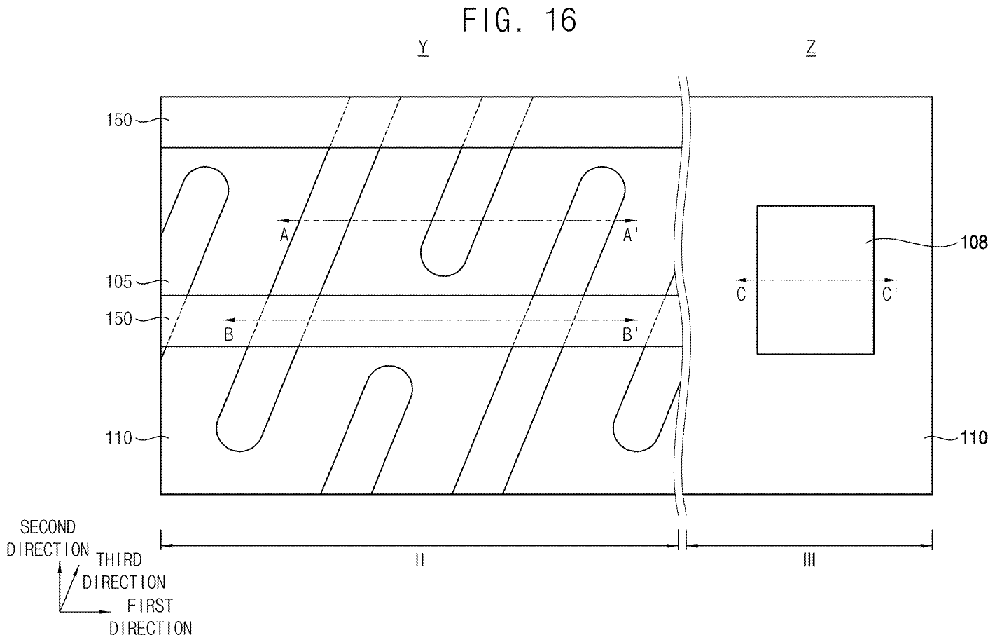

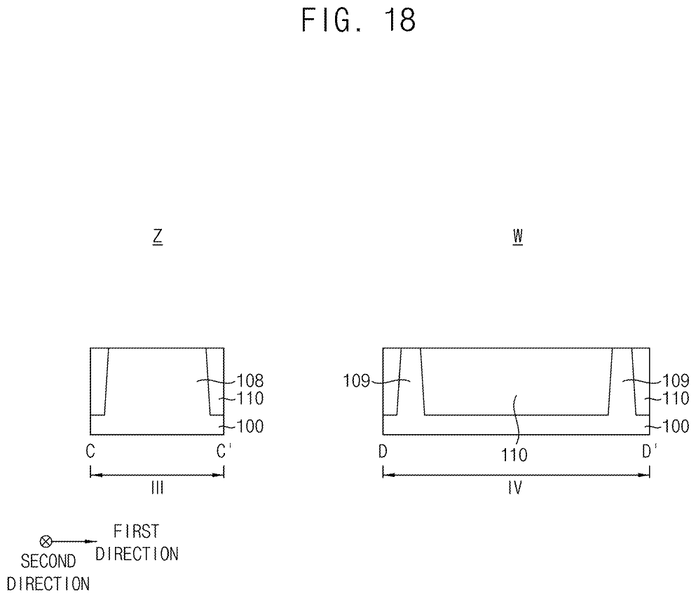

FIG. 15 is an enlarged cross-sectional view of a region X of FIG. 14, FIGS. 16, 19, 24, 35 and 48 are enlarged cross-sectional views of regions Y and Z of FIG. 15, FIGS. 17, 20, 22, 25, 27, 29, 31, 33, 36-37, 39, 41, 44, 46 and 49 include cross-sections taken along lines A-A′ and B-B′ of a region Y of corresponding plan views, and FIGS. 18, 21, 23, 26, 28, 30, 32, 34, 38, 40, 42-43, 45, 47, and 50-51 include cross-sections taken along lines C-C′ and D-D′ of regions Z and W of corresponding plan views.

This method may be an application of the method of forming patterns by the third and fourth exposure processes using the third photomask M3 illustrated with reference to FIGS. 1 to 13 to a manufacturing method of a DRAM device.

Hereinafter, forming a key structure by transferring a layout of an overlay key in the fourth region IV, i.e., the scribe lane region of a photomask, which is similar to the third photomask M3 of FIG. 4 and used in the third and fourth exposure processes, is illustrated, as non-limiting examples.

Each of the third and fourth exposure processes may be performed by the photomask, and a layout of patterns in the first region I, i.e., the chip region of the photomask may also be transferred to the wafer.

The third and fourth exposure processes may be performed so as to cover an entire portion of the wafer.

Hereinafter in the specification (and not necessarily in the claims), two directions among horizontal directions that are substantially parallel to an upper surface of a substrate, which are substantially perpendicular to each other, may be defined as first and second directions, respectively, and a direction among the horizontal directions, which has an acute angle with each of the first and second directions, may be defined as a third direction.

Referring to FIGS. 14 and 15, a substrate 100 may include first and fourth regions I and IV. The first region I may include second and third regions II and III.

The substrate 100 may be a wafer including silicon, germanium, silicon-germanium, or a III-V group compound semiconductor, such as GaP, GaAs, or GaSb. In example embodiments, the substrate 100 may be a silicon-on-insulator (SOI) wafer or a germanium-on-insulator (GOI) wafer.

The first region I of the substrate 100 may be a chip region in which patterns for semiconductor chips may be formed. In example embodiments, a plurality of first regions I may be spaced apart from each other in each of the first and second directions. Each of the first regions I may include the second region II in which memory cells may be formed, and thus may be referred to as a cell region, and the third region III surrounding the second region II in which peripheral circuit patterns for driving the memory cells may be formed. Thus, regions I, II and III may be referred to as a peripheral circuit region.

The fourth region IV of the substrate 100 may be formed between the first regions I. The fourth region IV may be a scribe lane region for cutting patterns on the substrate 100 into semiconductor chips.

Referring to FIGS. 16 to 18, first to third active patterns 105, 108 and 109 may be formed on the second to fourth regions II, III and IV, respectively, of the substrate 100. An isolation pattern 110 may be formed on the substrate 100 to cover sidewalls of the first to third active patterns 105, 108 and 109.

The first to third active patterns 105, 108 and 109 may be formed by removing an upper portion of the substrate 100 to form a first recess. A plurality of first active patterns 105 may be spaced apart from each other in the first and second directions. Each of the first active patterns 105 may extend in the third direction.

The isolation pattern 110 may be formed by forming an isolation layer on the substrate 100 to fill the first recess and planarizing the isolation layer until upper surfaces of the first to third active patterns 105, 108 and 109 may be exposed. In example embodiments, the planarization process may include a chemical mechanical polishing (CMP) process and/or an etch back process.

After an impurity region is formed in the substrate 100 by performing, e.g., an ion implantation process, the first active pattern 105 and the isolation pattern 110 on the second region II of the substrate 100 may be partially etched to form a second recess extending in the first direction.

A first gate structure 160 may be formed in the second recess. The first gate structure 160 may include a first gate insulation layer 130 on a surface of the first active pattern 105 exposed by the second recess, a first gate electrode 140 on the first gate insulation layer 130 to fill a lower portion of the second recess, and a first gate mask 150 on the first gate electrode 140 to fill an upper portion of the second recess. The first gate structure 160 may extend in the first direction, and a plurality of first gate structures 160 may be spaced apart from each other in the second direction.

The first gate insulation layer 130 may be formed by performing a thermal oxidation process on the surface of the first active pattern 105 exposed by the second recess, and thus, the first gate insulation layer 130 may include, for example, silicon oxide.

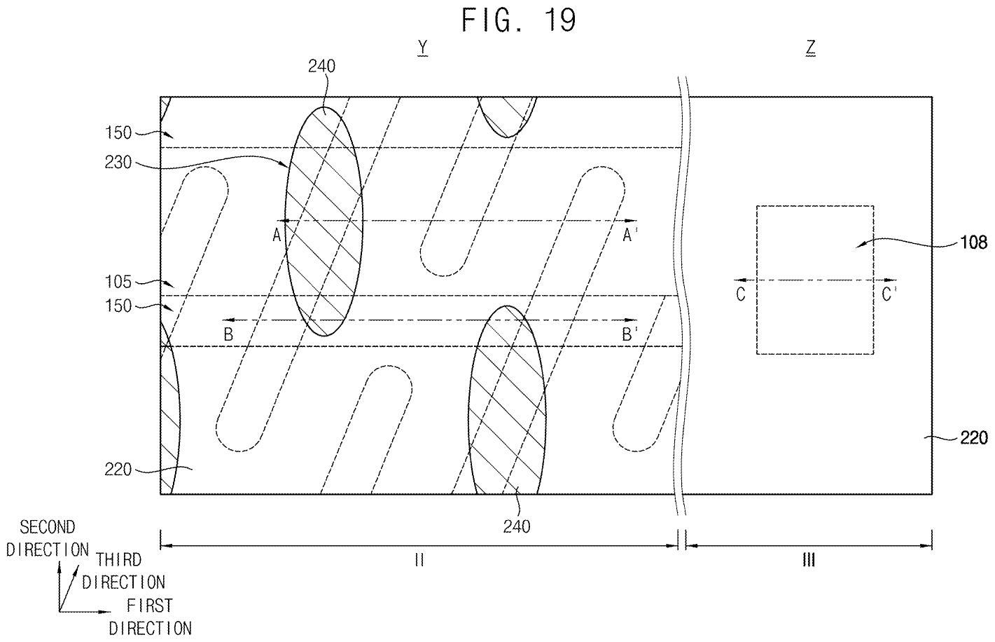

Referring to FIGS. 19 to 21, a thermal oxidation process may be performed on an upper surface of the second active pattern 108 on the third region III of the substrate 100 to form a second gate insulation layer 600. An insulation layer structure 200 may be formed on the first and third active patterns 105 and 109 and the isolation pattern 110 on the second and fourth regions II and IV of the substrate 100.

In example embodiments, the insulation layer structure 200 may include first, second, and third insulation layers 170, 180, and 190 sequentially stacked. The first and third insulation layers 170 and 190 may include an oxide, e.g., silicon oxide, and the second insulation layer 180 may include a nitride, e.g., silicon nitride.

A first conductive layer 210 and a first mask 220 may be sequentially formed on the insulation layer structure 200, the second gate insulation layer 600, the isolation pattern 110, the first conductive layer 210, and the insulation layer structure 200 may be etched using the first mask 220 as an etching mask to form a first opening 230 exposing the first active pattern 105 on the second region II of the substrate 100.

The first conductive layer 210 may include, for example, polysilicon doped with impurities. The first mask 220 may include a nitride, e.g., silicon nitride.

During the etching process, upper portions of the first active pattern 105, the isolation pattern 110 and the first gate mask 150 exposed by the first opening 230 may be also etched to form a third recess. That is, a bottom of the first opening 230 may be referred to as the third recess.

In example embodiments, the first opening 230 may expose an upper surface of a central portion of each of the first active patterns 105 extending in the third direction. Thus a plurality of first openings 230 may be formed in the first and second directions on the second region II of the substrate 100.

A second conductive layer 240 may be formed to fill the first opening 230.

In example embodiments, the second conductive layer 240 may be formed by forming a preliminary second conductive layer on the first active pattern 105, the isolation pattern 110, the first gate mask 150, and the first mask 220 to fill the first opening 230, and removing an upper portion of the preliminary second conductive layer through a CMP process and/or an etch bask process. The second conductive layer 240 may have an upper surface that is substantially coplanar with an upper surface of the first conductive layer 210.

In example embodiments, a plurality of second conductive layers 240 may be spaced apart from each other in the first and second directions on the second region II of the substrate 100. The second conductive layer 240 may include, for example, doped polysilicon, and may be merged with the first conductive layer 210.

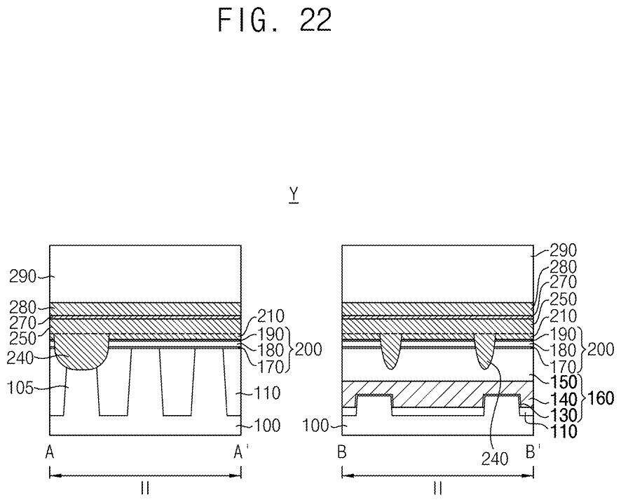

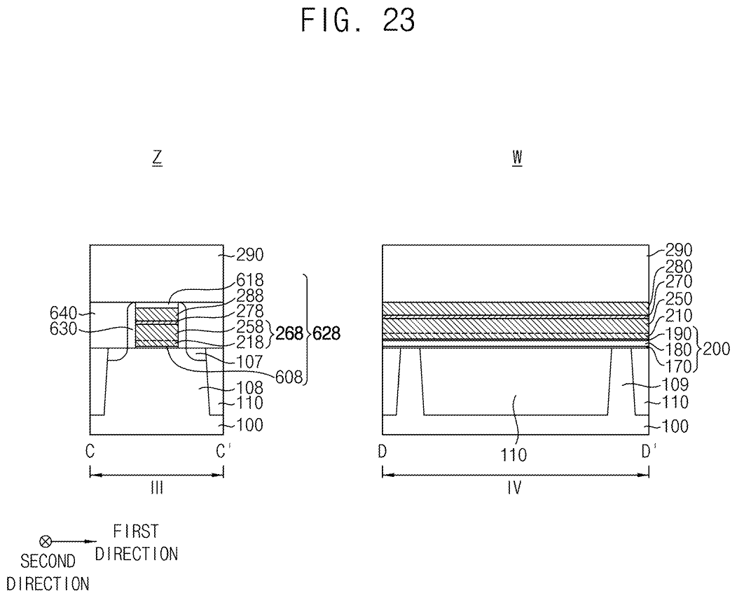

Referring to FIGS. 22 and 23, after removing the first mask 220, a third conductive layer 250, a barrier layer 270, and a first metal layer 280 may be sequentially formed on the first and second conductive layers 210 and 240.

In example embodiments, the third conductive layer 250 may include a material that is substantially the same as that of the first and second conductive layers 210 and 240. That is, the third conductive layer 250 may include doped polysilicon. Thus, in some embodiments, the doped polysilicon may be merged with the first and second conductive layers 210 and 240. The barrier layer 270 may include a metal nitride, e.g., titanium nitride, tantalum nitride, tungsten nitride, etc. The first metal layer 280 may include a metal, e.g., tungsten, titanium, tantalum, etc.

A second mask (not shown) may be formed to cover portions of the first metal layer 280 on the second and fourth regions II and IV of the substrate 100. A second gate mask 618 may be formed to partially cover a portion of the first metal layer 280 on the third region III of the substrate 100. The first metal layer 280, the barrier layer 270, the third conductive layer 250, the first conductive layer 210 and the second gate insulation layer 600 may be sequentially etched using the second mask and the second gate mask 618 as an etching mask.

Thus, a second gate structure 628 may be formed on the third region III of the substrate 100. The second gate structure 628 may include a second gate insulation pattern 608, a second conductive pattern 218, a sixth conductive pattern 258, a second barrier pattern 278, a second metal pattern 288, and the second gate mask 618 sequentially stacked on the second active pattern 108. The second and sixth conductive patterns 218 and 258 may include the same material, and thus may be merged with each other to form a second gate electrode 268.

A gate spacer 630 may be formed to cover a sidewall of the second gate structure 628, and impurities may be implanted into an upper portion of the second active pattern 108 adjacent the second gate structure 628 to form a source/drain layer 107.

After removing the second mask, a first insulating interlayer may be formed on the second to fourth regions II, III and IV of the substrate 100. The first insulating interlayer may be planarized until the first metal layer 280 and the second gate mask 618 are exposed to form a first insulating interlayer pattern 640 surrounding the second gate structure 628 and the gate spacer 630 on the third region III of the substrate 100. The first insulating interlayer pattern 640 may include an oxide, e.g., silicon oxide.

A capping layer 290 may be formed on the first metal layer 280, the first insulating interlayer pattern 640 and the second gate mask 618. The capping layer 290 may include a nitride, e.g., silicon nitride.

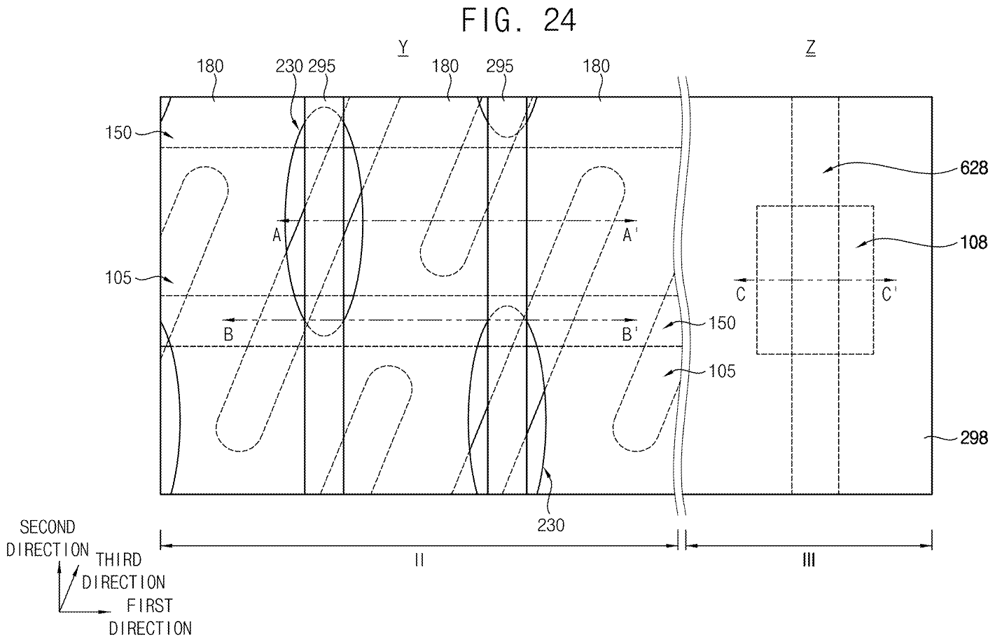

Referring to FIGS. 24 to 26, a portion of the capping layer 290 on the second and fourth regions II and IV of the substrate 100 may be etched to form first and third capping patterns 295 and 299, respectively, and the first metal layer 280, the barrier layer 270, the third conductive layer 250, the first and second conductive layers 210 and 240, and the third insulation layer 190 may be sequentially etched using the first and third capping patterns 295 and 299 as an etching mask.

In example embodiments, the first capping pattern 295 may extend in the second direction, and a plurality of first capping patterns 295 may be spaced apart from each other in the first direction on the second region II of the substrate 100. Additionally, the third capping pattern 299 may extend in the second direction, and a plurality of third capping patterns 299 may be spaced apart from each other in the first direction on the fourth region IV of the substrate 100. A portion of the capping layer 290 on the third region III of the substrate 100 may remain as a second capping pattern 298.

By the etching process in the second region II of the substrate 100, a fourth conductive pattern 245, a fifth conductive pattern 255, a first barrier pattern 275, a first metal pattern 285, and the first capping pattern 295 may be sequentially stacked on the first active pattern 105, the isolation pattern 110, and the first gate mask 150 in the first opening 230. A third insulation pattern 195, a first conductive pattern 215, the fifth conductive pattern 255, the first barrier pattern 275, the first metal pattern 285, and the first capping pattern 295 may be sequentially stacked on the second insulation layer 180 of the insulation layer structure 200 at an outside of the first opening 230.

As illustrated above, the first to third conductive layers 210, 240 and 250 may be merged with each other, and thus the fourth and fifth conductive patterns 245 and 255 sequentially stacked. The first and fifth conductive patterns 215 and 255 sequentially stacked may each form one first conductive structure 265. Hereinafter, the first conductive structure 265, the first barrier pattern 275, the first metal pattern 285, and the first capping pattern 295 sequentially stacked may be referred to as the bit line structure 305.

In example embodiments, the bit line structure 305 may extend in the second direction on the second region II of the substrate 100. A plurality of bit line structures 305 may be spaced apart from each other in the first direction.

In the fourth region IV of the substrate 100, a sixth insulation pattern 199, a third conductive pattern 219, a seventh conductive pattern 259, a third barrier pattern 279, a third metal pattern 289 and a third capping pattern 299 may be sequentially stacked on the second insulation layer 180 of the insulation layer structure 200. The third and seventh conductive patterns 219 and 259 sequentially stacked may form a second conductive structure 269. Hereinafter, the sixth insulation pattern 199, the second conductive structure 269, the third barrier pattern 279, the third metal pattern 289 and the third capping pattern 299 sequentially stacked may be referred to as a key structure 309.

In example embodiments, the key structure 309 may extend in the second direction on the fourth region IV of the substrate 100. A plurality of key structures 309 may be spaced apart from each other in the first direction. An upper surface of the key structure 309 may be substantially coplanar with an upper surface of the bit line structure 305.

A second opening 705 may be formed between neighboring ones of the bit line structures 305 on the second region II of the substrate 100 to extend in the second direction. The second opening 705 may expose an upper surface of the second insulation layer 180 to be connected with the first opening 230. The second opening 705 may have a first width W1 in the first direction. Additionally, a first trench 709 may be formed between neighboring ones of the key structures 309 on the fourth region IV of the substrate 100 to extend in the second direction. The first trench 709 may expose an upper surface of the second insulation layer 180, and may have a second width W2 greater than the first width W1 in the first direction. That is, a distance between the key structures 309 spaced apart from each other in the first direction may be greater than a distance between the bit line structures 305 spaced apart from each other in the first direction. In example embodiments, the first trench 709 may have a vertical sidewall substantially perpendicular to the upper surface of the substrate 100.

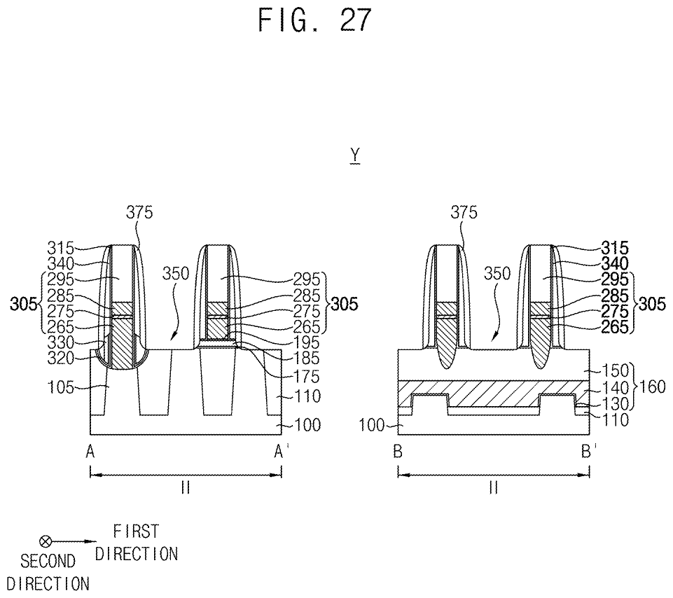

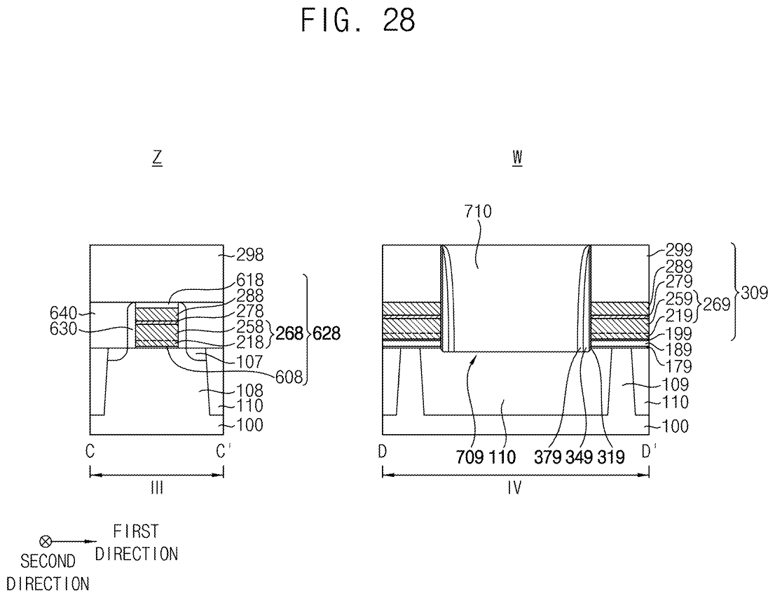

Referring to FIGS. 27 and 28, a first spacer layer may be formed on upper surfaces of the first active pattern 105, the isolation pattern 110 and the first gate mask 150 exposed by the first opening 230. A sidewall of the first opening 230, the second insulation layer 180, and the second and third capping patterns 298 and 299 that cover the bit line structure 305 and the key structure 309, and fourth and fifth insulation layers may be sequentially formed on the first spacer layer.

The first spacer layer may also cover a sidewall of the third insulation pattern 195 between the second insulation layer 180 and the bit line structure 305. The fifth insulation layer may fill the first opening 230.

The fourth and fifth insulation layers may be etched by an etching process. In example embodiments, the etching process may be performed by a wet etch process, and other portions of the fourth and fifth insulation layers except for a portion in the first opening 230 may be removed. Thus, most of an entire surface of the first spacer layer, that is, an entire surface except for a portion thereof in the first opening 230 may be exposed. Portions of the fourth and fifth insulation layers remaining in the first opening 230 may form seventh and eighth insulation patterns 320 and 330, respectively.

A second spacer layer may be formed on the exposed surface of the first spacer layer. The seventh and eighth insulation patterns 320 and 330 in the first opening 230, and may be anisotropically etched to form third and fourth spacers 340 and 349 on the surface of the first spacer layer and the seventh and eighth insulation patterns 320 and 330 to cover a sidewall of the bit line structure 305 and a sidewall of the key structure 309, respectively. The third and fourth spacers 340 and 349 may include an oxide, e.g., silicon oxide.

A dry etching process may be performed using the first to third capping patterns 295, 298 and 299 and the third and fourth spacers 340 and 349 as an etching mask to form a third opening 350 exposing the upper surface of the first active pattern 105 on the second region II of the substrate 100. The upper surface of the isolation pattern 110 and the upper surface of the first gate mask 150 may also be exposed by the third opening 350. Additionally, by the dry etching process, the first trench 709 may be enlarged downwardly to expose an upper surface of the isolation pattern 110 on the fourth region IV of the substrate 100.

By the dry etching process, portions of the first spacer layer on upper surfaces of the first to third capping patterns 295, 298 and 299 and an upper surface of the second insulation layer 180 may be removed. Thus, a first spacer 315 covering the sidewall of the bit line structure 305 and a second spacer 319 covering the sidewall of the key structure 309 may be formed. The first and second spacers 315 and 319 may include a nitride, e.g., silicon nitride. Additionally, during the dry etching process, the first and second insulation layers 170 and 180 may be partially removed, such that first and second insulation patterns 175 and 185 may remain under the bit line structure 305. Fourth and fifth insulation patterns 179 and 189 may remain under the key structure 309. The first to third insulation patterns 175, 185 and 195 that are sequentially stacked under the bit line structure 305 may form a first insulation pattern structure. Fourth to sixth insulation patterns 179, 189 and 199 that are sequentially stacked under the key structure 309 may form a second insulation pattern structure.

A third spacer layer may be formed on the upper surfaces of the first to third capping patterns 295, 298 and 299, outer sidewalls of the third and fourth spacers 340 and 349, portions of upper surfaces of the seventh and eighth insulation patterns 320 and 330. The upper surfaces of the first active pattern 105, the isolation pattern 110 and the first gate mask 150 exposed by the third opening 350 may be anisotropically etched to form a fifth spacer 375 covering the sidewall of the bit line structure 305 and a sixth spacer 379 covering the sidewall of the key structure 309. The fifth and sixth spacers 375 and 379 may include a nitride, e.g., silicon nitride.

The first, third and fifth spacers 315, 340 and 375, which are sequentially stacked in a horizontal direction substantially parallel to the upper surface of the substrate 100 from the sidewall of the bit line structure 305 on the second region II of the substrate 100, may be referred to as a first preliminary spacer structure, and the second, fourth and sixth spacers 319, 349 and 379 sequentially stacked in the horizontal direction from the sidewall of the key structure 309 on the fourth region IV of the substrate 100 may be referred to as a second spacer structure.

A second insulating interlayer may be formed on the substrate 100 to cover the bit line structure 305, the key structure 309, the second capping pattern 298, the first preliminary spacer structure and the second spacer structure. An upper portion of the second insulating interlayer may be planarized until the upper surfaces of the first to third capping patterns 295, 298 and 299 are exposed. An upper portion of the second insulating interlayer in the first and second openings 230 and 705 on the second region II of the substrate 100 may be removed to form a second insulating interlayer pattern 710 filling the first trench 709 on the fourth region IV of the substrate 100. The second insulating interlayer pattern 710 may include an oxide, e.g., silicon oxide.

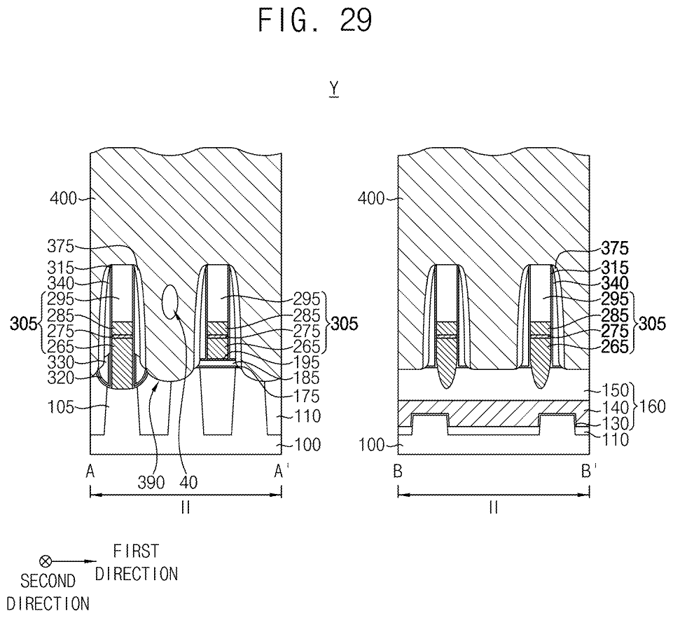

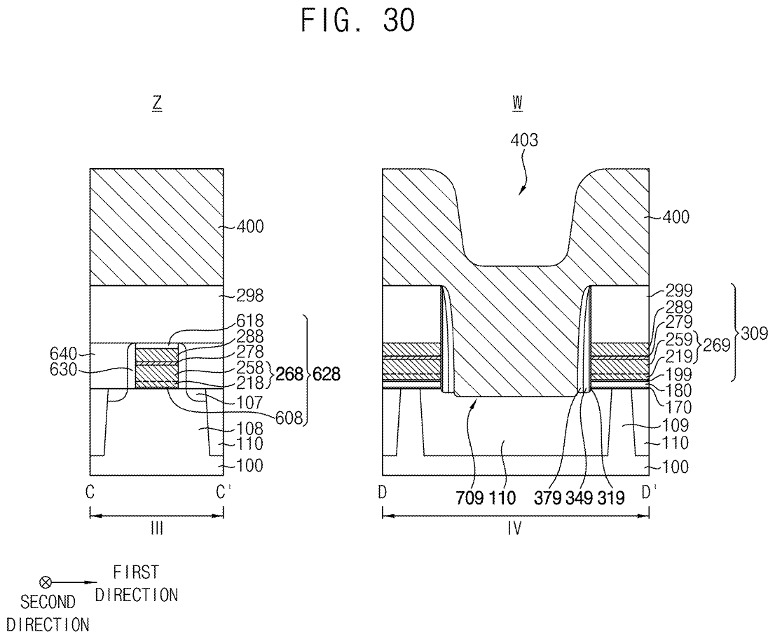

Referring to FIGS. 29 and 30, an upper portion of the first active pattern 105 may be removed by an etching process to form a fourth recess 390 connected to the third opening 350.

The second insulating interlayer pattern 710 on the fourth region IV of the substrate 100 may be removed to form the first trench 709 again. An upper portion of the isolation pattern 110 under the second insulating interlayer pattern 710 may be partially etched. Thus, a bottom of the first trench 709 may be lower than the bottom of each of the key structures 309, and may be also lower than an upper surface of the third active pattern 109.

A lower contact plug layer 400 may be formed to fill the third opening 350 and the fourth recess 390 on the second region II of the substrate 100 and to fill the first trench 709 in the fourth region IV of the substrate 100.

The bit line structures 305 having the first preliminary spacer structures in the respective sidewalls thereof may be spaced apart from each other in the first direction in the second region II of the substrate 100. The key structures 309 having the second spacer structures on the respective sidewalls thereof may be spaced apart from each other in the first direction in the fourth region IV of the substrate 100. Thus, the lower contact plug layer 400 may have an uneven upper surface.

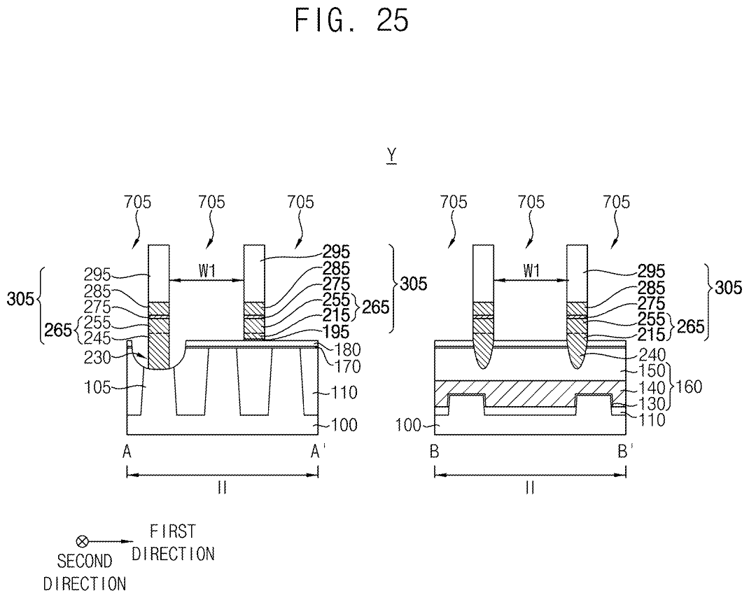

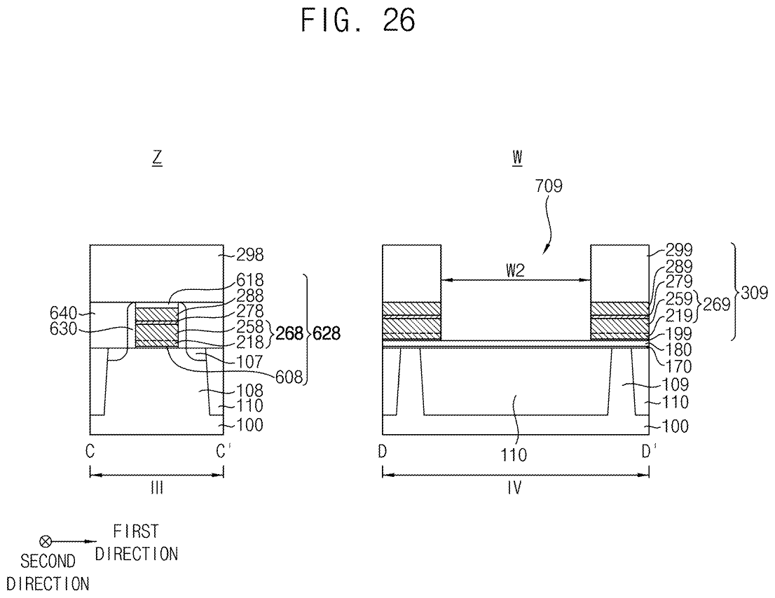

For example, a width in the first direction of the third opening 350 may be less than the first width W1 in the first direction of the second opening 705 (refer to FIG. 25), and thus may be much less than the second width W2 in the first direction of the first trench 709. Accordingly, the lower contact plug layer 400 may not entirely fill the third opening 350 on the second region II of the substrate 100. thereby forming a first air gap 401. An upper surface of a portion of the lower contact plug layer 400 on the first trench 709 may be much lower than an upper surface of a portion of the lower contact plug layer 400 on the key structure 309 in the fourth region IV of the substrate 100.

In example embodiments, the lower contact plug layer 400 may include, e.g., doped polysilicon.

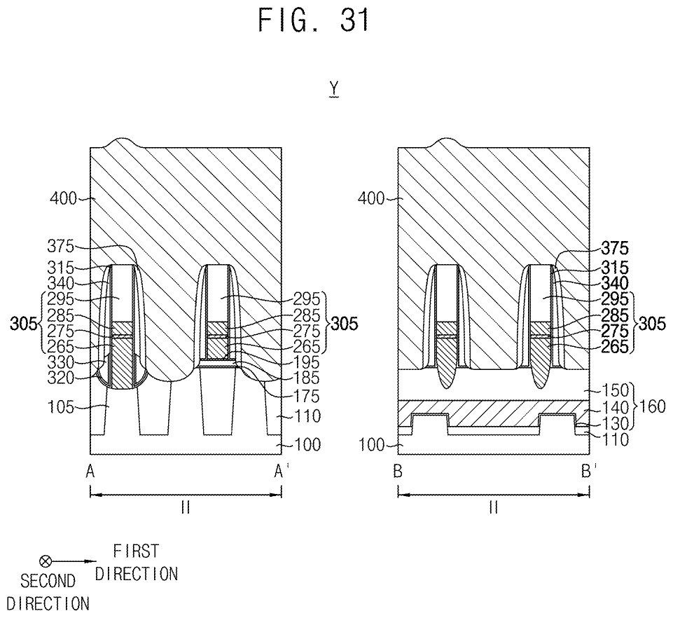

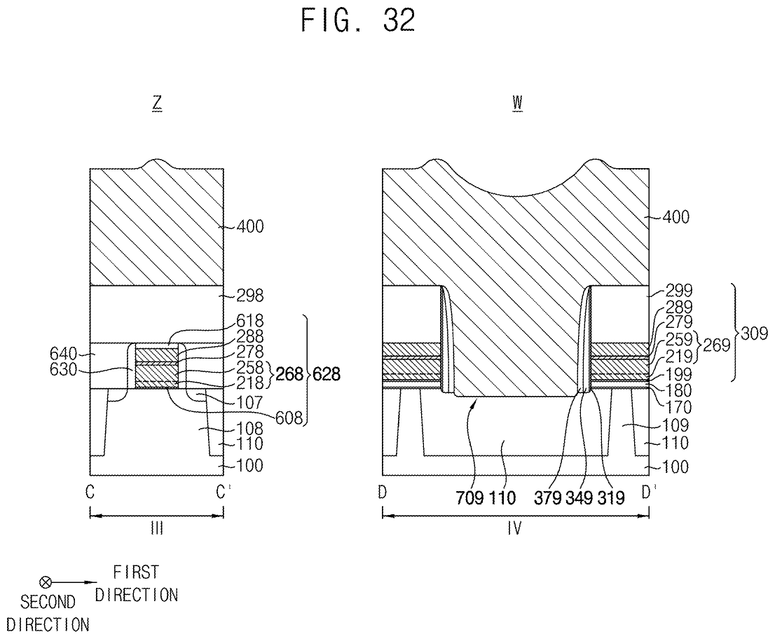

Referring to FIGS. 31 and 32, a melting process may be performed on the lower contact plug layer 400.

In example embodiments, the melting process may include a laser annealing process.

Thus, the flexibility of the lower contact plug layer 400 may be enhanced such that the first air gap 401 between the bit line structures 305 may be filled enough to disappear and such that the uneven upper surface of the lower contact plug layer 400 may be considerably planarized. For example, the height difference between the upper surface of the portion of the lower contact plug layer 400 on the first trench 709 and the upper surface of the portion of the lower contact plug layer 400 on the key structure 309 may be relieved in the fourth region IV of the substrate 100.

Due to the melting process, the upper surface of the lower contact plug layer 400 may have a wave-like shape.

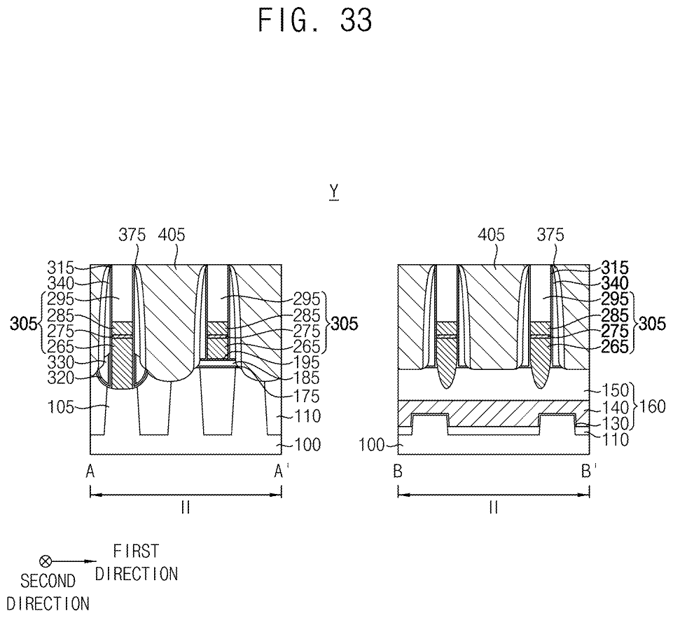

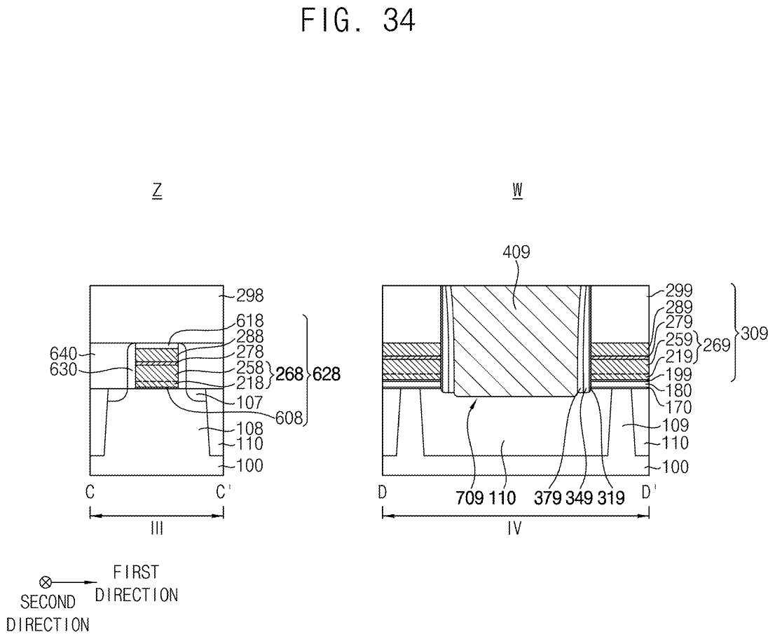

Referring to FIGS. 33 and 34, an upper portion of the lower contact plug layer 400 may be planarized until the upper surfaces of the first to third capping patterns 295, 298 and 299 are exposed. Thus, a lower contact plug 405 may be formed between the bit line structures 305, and a filling pattern 409 may be formed between the key structures 309.

The planarization process may include a CMP process. As illustrated above, since the height difference between the upper surfaces of portions of the lower contact plug layer 400 has been relieved, each of the lower contact plug 405 and the filling pattern 409 may have a flat upper surface. The upper surface of the portion of the lower contact plug 405 between the bit line structures 305 may be substantially coplanar with the upper surfaces of the bit line structures 305. The upper surface of the portion of the lower contact plug 405 between the key structures 309 may be substantially coplanar with the upper surfaces of the key structures 309. Accordingly, the upper surfaces of the portions of the lower contact plug 405 may have substantially the same height.

In example embodiments, each of the lower contact plug 405 and the filling pattern 409 may extend in the second direction, and a plurality of lower contact plugs 405 may be formed to be spaced apart from each other in the first direction.

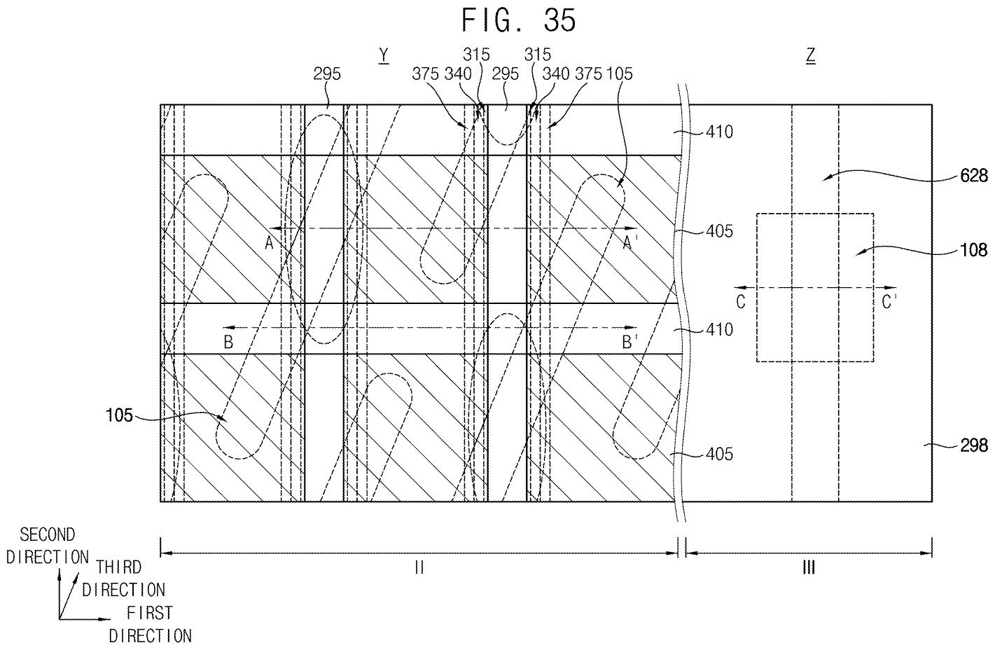

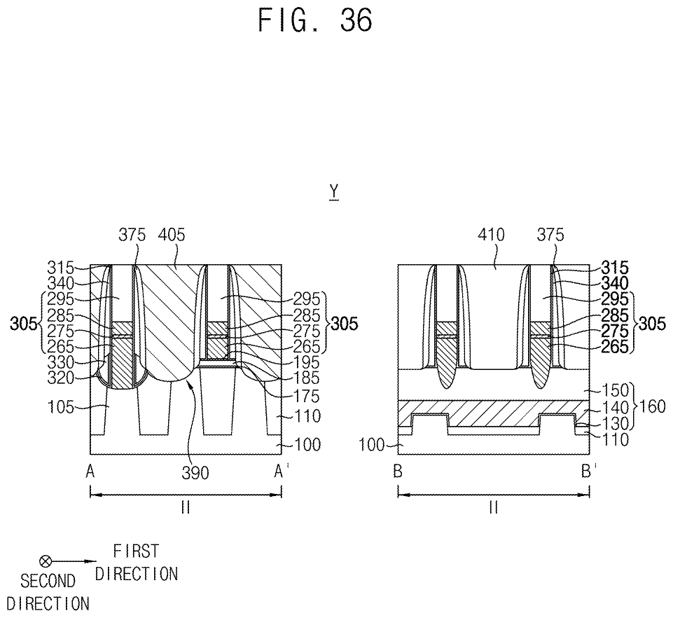

Referring to FIGS. 35 and 36, a third mask (not shown) including fourth openings, each of which may extend in the first direction, spaced apart from each other in the second direction may be formed on the first to third capping patterns 295, 298 and 299, the lower contact plug 405 and the filling pattern 409, and the lower contact plug 405 may be etched using the third mask as an etching mask.

In example embodiments, each of the fourth openings may overlap the first gate structure 160 in a vertical direction substantially perpendicular to the upper surface of the substrate 100 on the second region II of the substrate 100. By the etching process, a fifth opening may be formed to expose the upper surface of the first gate mask 150 of the first gate structure 160 between the bit line structures 305 on the second region II of the substrate 100.

After removing the third mask, a fourth capping pattern 410 may be formed on the second region II of the substrate 100 to fill the fifth opening. The fourth capping pattern 410 may include a nitride, e.g., silicon nitride. In example embodiments, the fourth capping pattern 410 may extend in the first direction between the bit line structures 305. A plurality of fourth capping patterns 410 may be formed in the second direction.

Thus, the lower contact plug 405 extending in the second direction between the bit line structures 305 may be divided into a plurality of pieces spaced apart from each other in the second direction by the fourth capping patterns 410 on the second region II of the substrate 100.

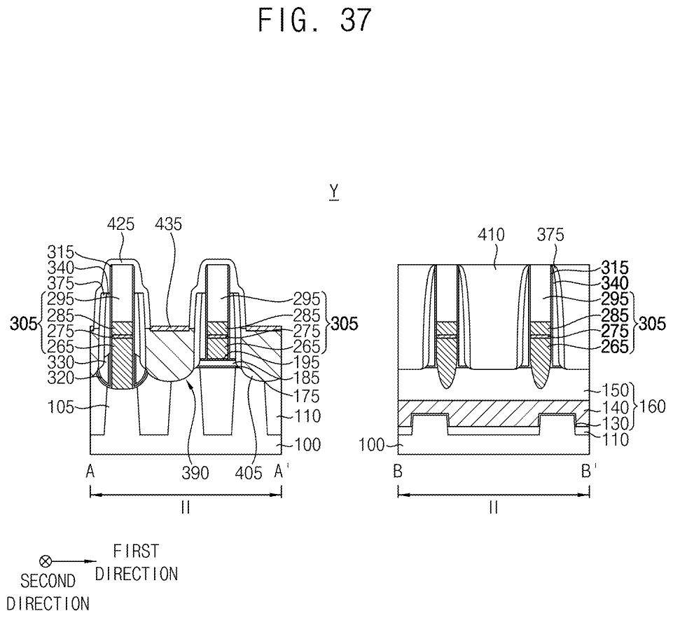

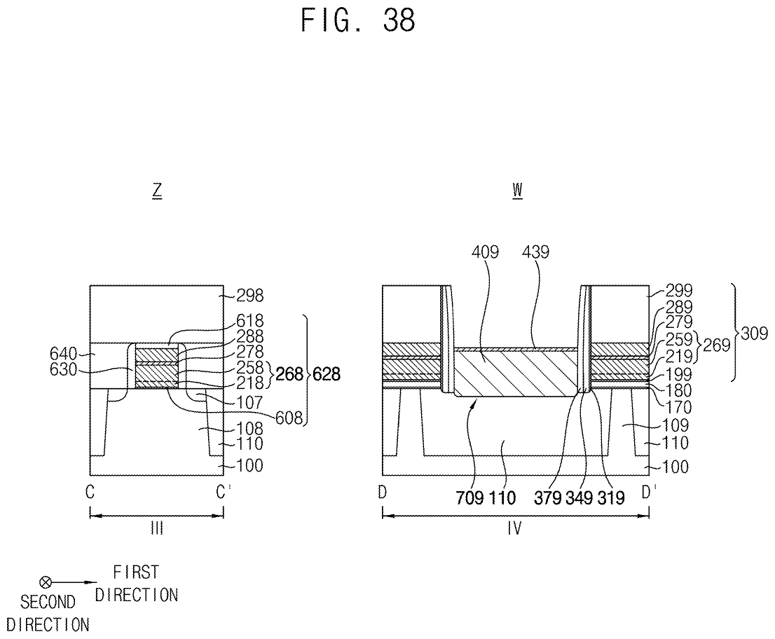

Referring to FIGS. 37 and 38, upper portions of the lower contact plug 405 and the filling pattern 409 may be removed.

In example embodiments, the upper portions of the lower contact plug 405 and the filling pattern 409 may be removed by an etch back process. As illustrated above, the upper surfaces of the lower contact plug 405 and the filling pattern 409 may have the same height, and thus the lower contact plug 405 and the filling pattern 409 may have a given thickness by the etch back process.

When the upper portion of the lower contact plug 405 is removed, an upper portion of the first preliminary spacer structure on the sidewall of the bit line structure 305 may be exposed, and upper portions of the third and fifth spacers 340 and 375 of the exposed first preliminary spacer structure may be removed.

An etch back process may be further performed to remove upper portions of the lower contact plug 405 and the filling pattern 409. Thus, the upper surface of the lower contact plug 405 may be lower than uppermost surfaces of the third and fifth spacers 340 and 375.

By the etch back process, the upper portions of the lower contact plug 405 and the filling pattern 409 may be removed and lower portions thereof may remain. The upper surfaces of the remaining portions of the lower contact plug 405 and the filling pattern 409 may be flat. However, due to the width difference between the lower contact plug 405 and the filling pattern 409, the upper surfaces of the lower contact plug 405 and the filling pattern 409 may not be coplanar with each other. For example, by the etch back process, the filling pattern 409 having a relatively large width when compared to the lower contact plug 405 having a relatively small width may be less etched, and thus the upper surface of the filling pattern 409 may be higher than the upper surface of the lower contact plug 405 after the etch back process.

A fourth spacer layer may be formed on the bit line structure 305, the first preliminary spacer structure, the second to fourth capping patterns 298, 299 and 410, the lower contact plug 405 and the filling pattern 409, and may be anisotropically etched such that a seventh spacer 425 may be formed to cover the first, third and fifth spacers 315, 340 and 375 on each of opposite sidewalls of the bit line structure 305 in the first direction and such that an upper surface of the lower contact plug 405 may not be covered by the seventh spacer 425 but is exposed.

First and second metal silicide patterns 435 and 439 may be formed on the exposed upper surfaces of the lower contact plug 405 and the filling pattern 409. In example embodiments, the first and second metal silicide patterns 435 and 439 may be formed by forming a second metal layer on the first to fourth capping patterns 295, 298, 299 and 410, the seventh spacer 425, the lower contact plug 405 and the filling pattern 409, thermally treating the second metal layer, and removing unreacted portion of the second metal layer. The first and second metal silicide patterns 435 and 439 may include, e.g., cobalt silicide, nickel silicide, titanium silicide, etc.

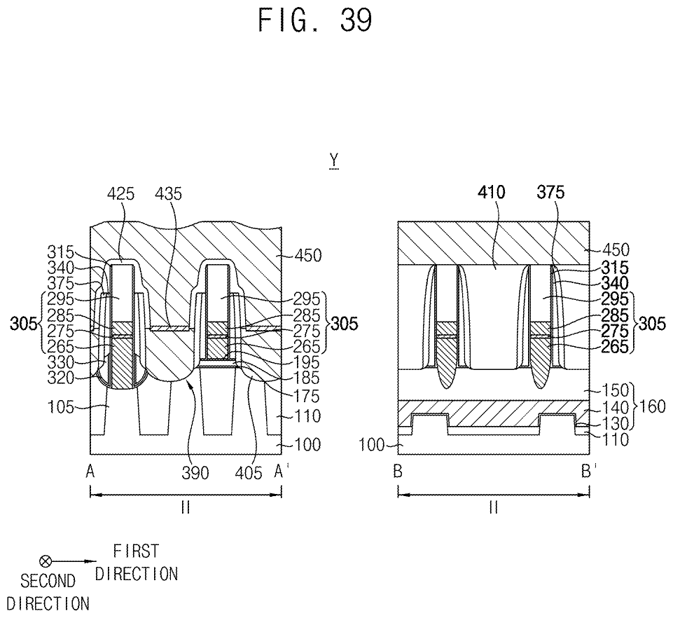

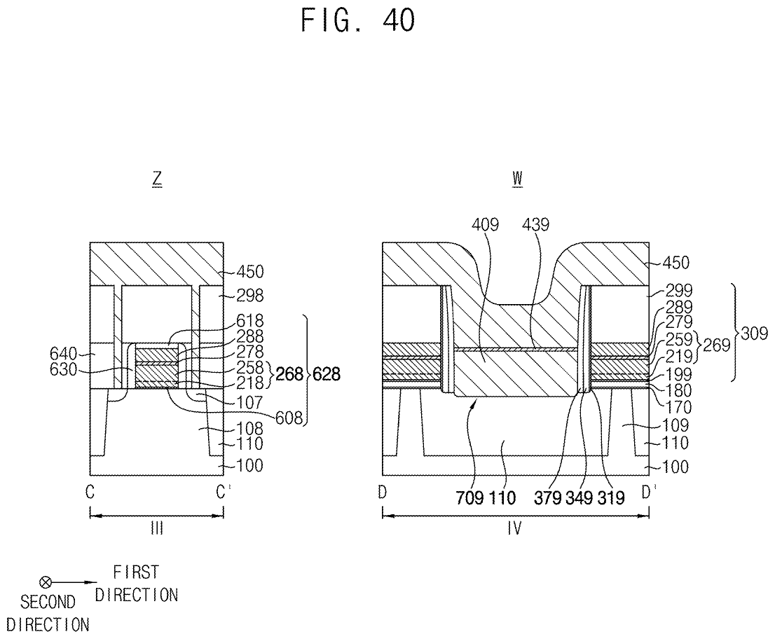

Referring to FIGS. 39 and 40, a first sacrificial layer may be formed on the first to fourth capping patterns 295, 298, 299 and 410, the seventh spacer 425, and the first and second metal silicide patterns 435 and 439. The first sacrificial layer may be planarized until the upper surfaces of the first to fourth capping patterns 295, 298, 299 and 410 are exposed. A first hole may be formed in the third region III of the substrate 100.

The first sacrificial layer may include, e.g., silicon-on-hardmask (SOH), amorphous carbon layer (ACL), etc.

The first hole may extend through the second capping pattern 298 and the first insulating interlayer pattern 640 to expose an upper surface of the source/drain layer 107 in the third region III of the substrate 100.

After removing the first sacrificial layer, an upper contact plug layer 450 may be formed on the first to fourth capping patterns 295, 298, 299 and 410, the first, third, fifth and seventh spacers 315, 340, 375 and 425, the first and second metal silicide patterns 435 and 439, the lower contact plug 405, the filling pattern 409 and the source/drain layer 107.

The bit line structures 305 having the first, third, fifth and seventh spacers 315, 340, 375 and 425 on sidewalls thereof may be spaced apart from each other in the first direction in the second region II of the substrate 100. The bit line structures 305 may have an upper surface higher than that of the first metal silicide pattern 435. The key structures 309 may be formed in the fourth region IV of the substrate 100. The key structures 309 may have an upper surface that is higher than the height of the second metal silicide pattern 439. Thus, an upper surface of the upper contact plug layer 450 may have an uneven upper surface.

In example embodiments, the upper contact plug layer 450 may be conformally formed on the key structures 309 and on the second metal silicide pattern 439 in the fourth region IV of the substrate 100. Thus, an upper surface of a portion of the upper contact plug layer 450 on the second metal silicide pattern 439 may be lower than an upper surface of a portion of the upper contact plug layer 450 on the key structure 309.

In example embodiments, the upper contact plug layer 450 may include a metal, e.g., tungsten.

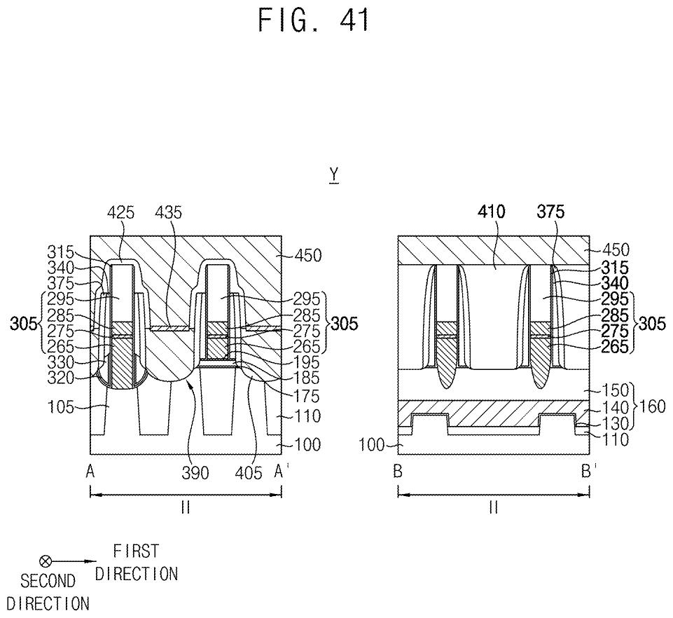

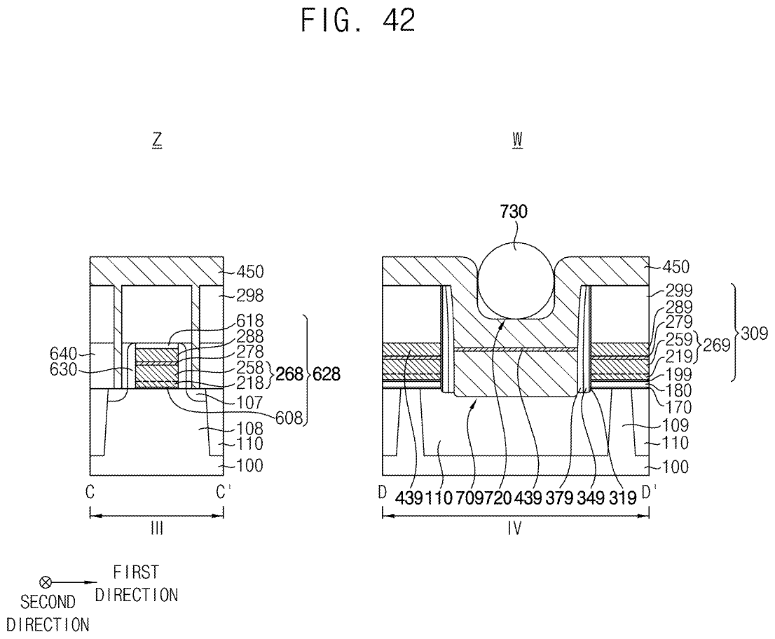

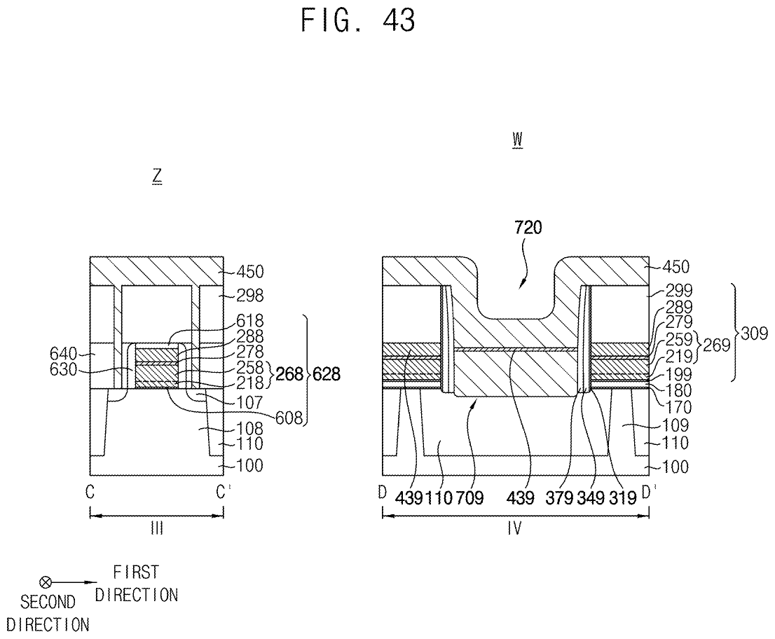

Referring to FIGS. 41 and 42, an upper portion of the upper contact plug layer 450 may be planarized by a CMP process.

The CMP process may be performed such that an upper surface of the upper contact plug layer 450 may be higher than the height of the bit line structures 305 and the key structures 309. That is, polishing of the stop layer may not be used, and thus it may be difficult to control time for the CMP process. However, there is a height difference between upper surfaces of portions of the upper contact plug layer 450 on the second metal silicide pattern 439 and the key structure 309, and thus the time for the CMP may be controlled by referring to the height difference.

By the CMP process, a portion of the upper contact plug layer 450 on the second and third regions II and III of the substrate 100 may have a flat upper surface, and a portion of the upper contact plug layer 450 on the fourth region IV of the substrate 100 may have a constant thickness on the key structures 309 and the second metal silicide pattern 439. A second trench 720 on an upper sidewall, an upper surface of the key structure 309, and an upper surface of the second metal silicide pattern 439 may have a flat bottom and a sidewall that is close to a right angle, For example, the side wall may be at an angle equal to or more than 75 degrees with respect to the upper surface of the substrate 100. That is, a sidewall of a portion of the upper contact plug layer 450 on the upper sidewall of the key structure 309 may be almost vertical.

A slurry particle 730 used in the CMP process may not be entirely removed but partially remain, and particularly, may remain in the second trench 720 having a concave shape. The slurry particle 730 may include, e.g., silicon oxide.

Referring to FIG. 43, a cleansing process may be performed so as to remove impurities generated in the CMP process.

By the cleansing process, a slurry particle 730 that may remain in the second trench 720 may be removed. For example, the second trench 720 may have a depth less than that of the first trench 709 (refer to FIG. 26) due to the filling pattern 409 and the second metal silicide pattern 439, Thus. an upper portion of the slurry particle 730 may be exposed above the second trench 720, so as to be easily removed by the cleansing process.

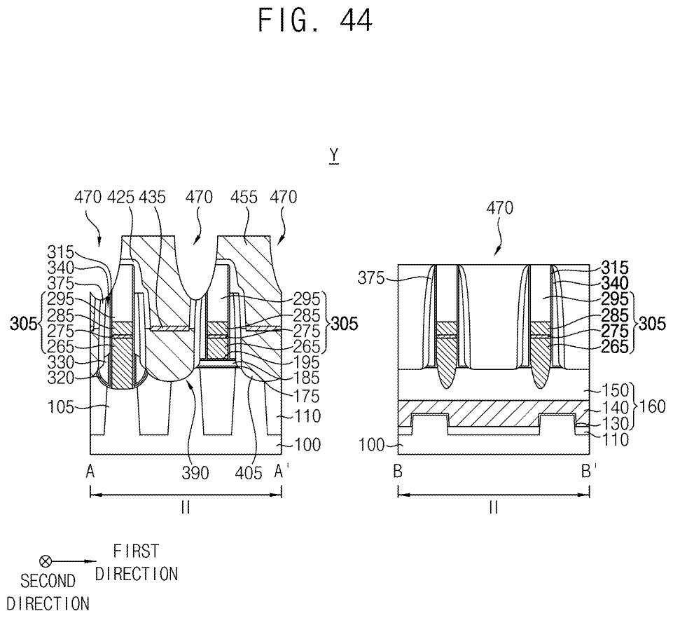

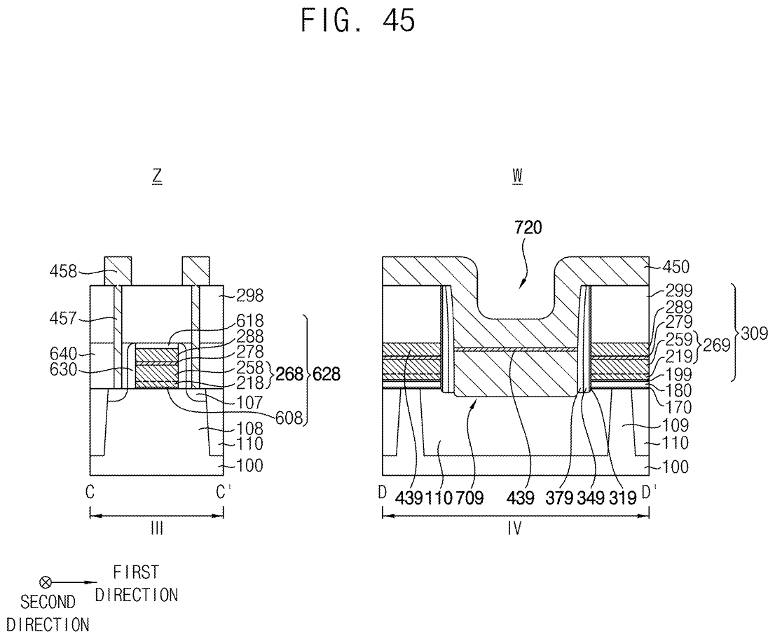

Referring to FIGS. 44 and 45, a portion of the upper contact plug layer 450 on the second region II of the substrate 100 may be etched to form a second hole 470 A portion of the upper contact plug layer 450 on the third region III of the substrate 100 may be patterned.

The second hole 470 may be formed by removing an upper portion of the upper contact plug layer 450, an upper portion of the first capping pattern 295, and upper portions of the first, fifth and seventh spacers 315, 375 and 425 on the second region II of the substrate 100. The second hole 470 may expose an upper surface of the third spacer 340.

When the second hole 470 is formed, the upper contact plug layer 450 may be divided into a plurality of upper contact plugs 455 in the second region II of the substrate 100. In example embodiments, the plurality of upper contact plugs 455 may be formed in the first and second directions, and may be arranged in a honeycomb pattern in a plan view. Each of the upper contact plugs 455 may have a shape of a circle, an ellipse, or a polygon.

The lower contact plug 405, the first metal silicide pattern 435 and the upper contact plug 455 sequentially stacked in the second region II of the substrate 100 may form a first contact plug structure.

When the upper contact plug layer 450 is patterned in the third region III of the substrate 100, a second contact plug 457 filling the first hole and a wiring 458 contacting an upper surface of the second contact plug 457 may be formed. The second contact plug 457 and the wiring 458 may be electrically connected to the source/drain layer 107. In an example embodiment, the wiring 458 may be electrically connected to the bit line structure 305 on the second region II of the substrate 100, and may apply electrical signals to the bit line structure 305.

In example embodiments, during the formation of the wiring 458, the second trench 720 may be used as an overlay key. As discussed above, the second trench 720 may have an almost vertical sidewall, so as to serve well as the overlay key.

A portion of the upper contact plug layer 450 remaining in the fourth region IV of the substrate 100 may be referred to as a third conductive structure 459.

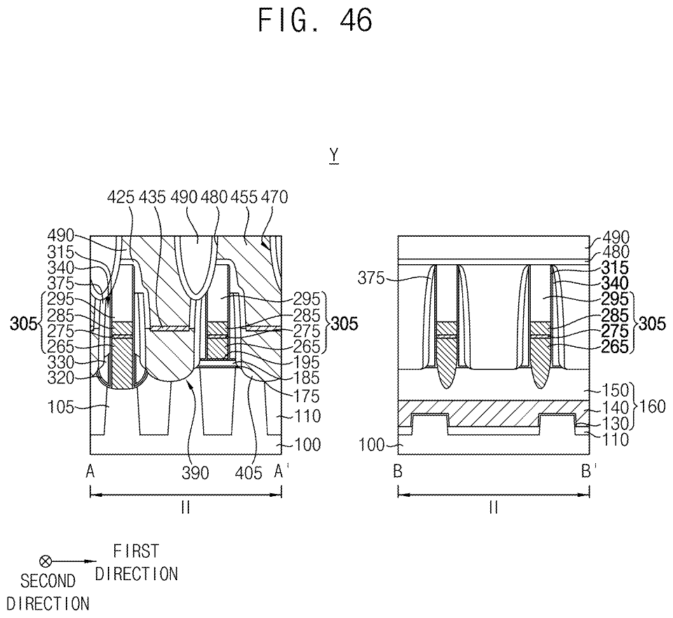

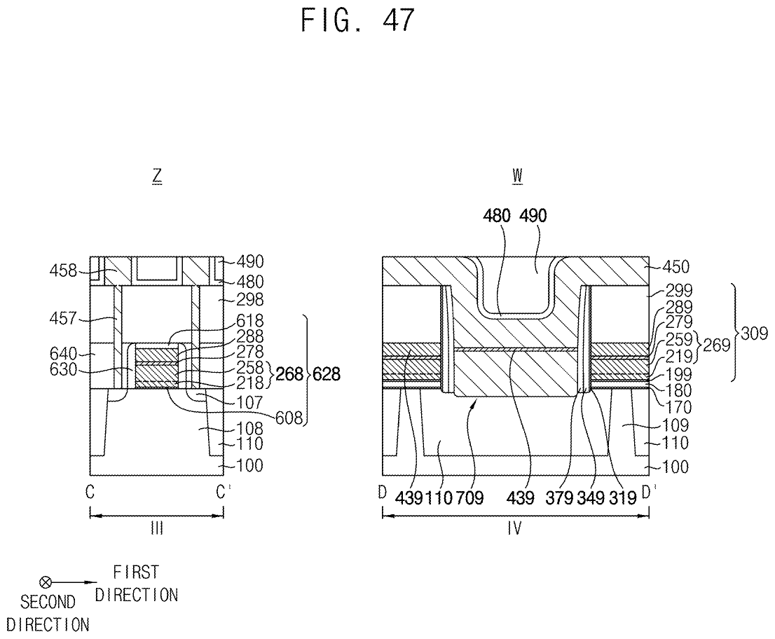

Referring to FIGS. 46 and 47, the third spacer 340 exposed by the second hole 470 may be removed to form a second air gap 345 connected to the second hole 470. The third spacer 340 may be removed by, e.g., a wet etching process.

In example embodiments, not only is a portion of the third spacer 340 on the sidewall of the bit line structure 305 extending in the second direction directly exposed by the second hole 470 but also other portions of the third spacer 340 that are parallel in the horizontal direction to the directly exposed portion thereof may be removed. That is, not only is the portion of the third spacer 340 exposed by the second hole 470 not to be covered by the upper contact plug 455 but also a portion of the third spacer 340 adjacent to the exposed portion in the second direction to be covered by the fourth capping pattern 410 and a portion of the third spacer 340 adjacent to the exposed portion in the second direction to be covered by the upper contact plug 455 may be all removed.

Third and fourth insulating interlayers 480 and 490 may be sequentially stacked to fill the second hole 470 in the second region II of the substrate 100, a space between the wirings 458 on the third region III of the substrate 100, and the second trench 720 on the second region II of the substrate 100. The third and fourth insulating interlayers 480 and 490 may be also sequentially stacked on the fourth capping pattern 410.

The third insulating interlayer 480 may include a material having a low gap filling characteristic. Thus, the second air gap 345 under the second hole 470 may not be filled. The second air gap 345 may be also referred to as an air spacer 345. The second air gap 345 may form a first spacer structure together with the first, fifth and seventh spacers 315, 375 and 425. That is, the second air gap 345 may be a spacer including that includes air. The fourth insulating interlayer 490 may include a nitride, e.g., silicon nitride.

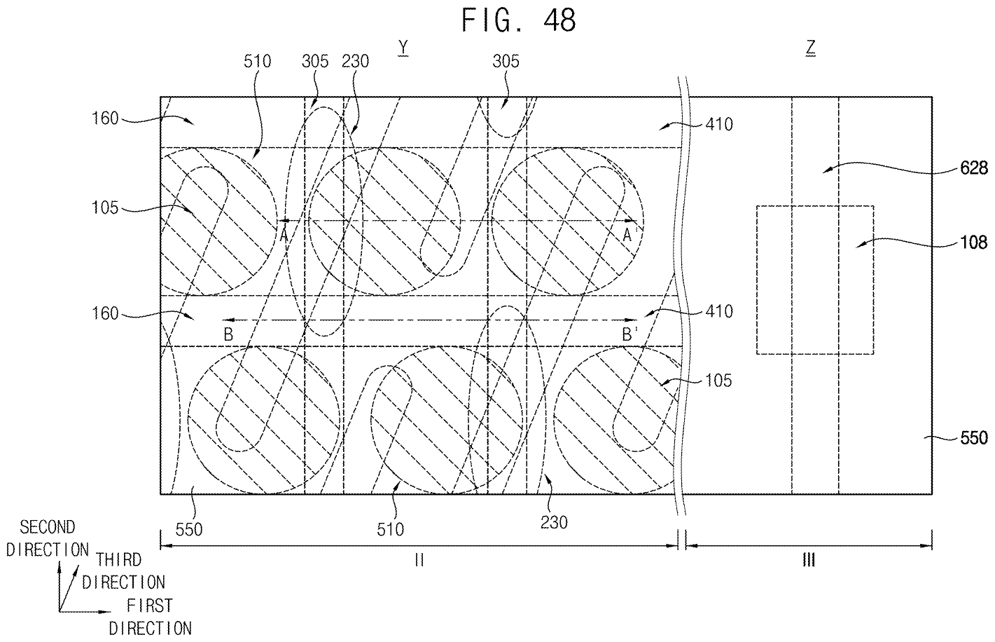

Referring to FIGS. 48 to 50, a capacitor 540 may be formed to contact the upper surface of the upper contact plug 455.

In particular, an etch stop layer 500 and a mold layer (not shown) may be sequentially formed on the upper contact plug 455, the third and fourth insulating interlayers 480 and 490, the wiring 458 and the third conductive structure 459, may be partially etched to form a sixth opening partially exposing the upper surface of the upper contact plug 455.

A lower electrode layer (not shown) may be formed on a sidewall of the sixth opening, the exposed upper surface of the upper contact plug 455 and the mold layer. A second sacrificial layer (not shown) may be formed on the lower electrode layer to fill the sixth opening. The lower electrode layer and the second sacrificial layer may be planarized until an upper surface of the mold layer is exposed to divide the lower electrode layer. The second sacrificial layer and the mold layer may be removed by, e.g., a wet etching process. Thus a lower electrode 510 having a cylindrical shape may be formed on the exposed upper surface of the upper contact plug 455. In some implementations, the lower electrode 510 may have a pillar shape filling the sixth opening.

A dielectric layer 520 may be formed on a surface of the lower electrode 510 and the etch stop layer 500 An upper electrode 530 may be formed on the dielectric layer 520 such that the capacitor 540 including the lower electrode 510, the dielectric layer 520, and the upper electrode 530 may be formed.

A fifth insulating interlayer 550 may be formed to cover the capacitor 540 in the second to fourth regions II, III and IV of the substrate 100. The fifth insulating interlayer 550 may include an oxide, e.g., silicon oxide. Upper wirings (not shown) may be further formed to form semiconductor chips on the respective first regions I of the substrate 100.

A dicing process or a sawing process may be performed such that the semiconductor chips on the respective first regions I of the substrate 100 may be divided, and thus the fabrication of the semiconductor device may be completed.

FIG. 51 shows only a portion of the semiconductor device taken along a line D-E of FIG. 15. The portion remains according to the partial removal of the semiconductor device on the region W in the fourth region IV of the substrate 100 by the dicing process.

The photomask and the method of manufacturing the semiconductor device may be applied to a method of manufacturing, e.g., logic devices such as CPUs, MPUs, APs, etc., volatile memory devices such as SRAM devices, DRAM devices, etc., or non-volatile memory devices such as flash memory devices, PRAM devices, MRAM devices, RRAM devices, etc.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A photolithography method using a photolithography system including a light source, a photomask stage, a projection optical system and a wafer stage, the projection optical system including an anamorphic lens, and the method comprising:
after mounting a wafer and a photomask on the wafer stage and the photomask stage, respectively, performing a first exposure process using the photomask to transfer layouts of patterns included in the photomask to a first half field of the wafer; and
after changing a relative position of the photomask with respect to the wafer, performing a second exposure process to transfer the layouts of the patterns included in the photomask to a second half field of the wafer.

2. The photolithography method as claimed in claim 1, wherein each of the first and second half fields has an area corresponding to half an area of a field, the field being a region covered by a single exposure process when the projection optical system includes an isomorphic lens.

3. The photolithography method as claimed in claim 1, wherein:
horizontal directions substantially parallel to an upper surface or a lower surface of the photomask stage include x-direction and y-direction substantially perpendicular to each other,
changing the relative position of the photomask with respect to the wafer includes changing a relative position of the photomask with respect to the wafer in the y-direction, and
a reduction rate in the y-direction of the anamorphic lens is twice a reduction rate in the x-direction of the anamorphic lens.

4. The photolithography method as claimed in claim 3, wherein the photomask includes chip regions spaced apart from each other in each of the x-direction and the y-direction and a scribe lane region surrounding the chip regions, and
wherein an alignment key, an overlay key or a test element group {TEG} is formed in the scribe lane region.

5. The photolithography method as claimed in claim 4, wherein the layouts of the patterns transferred to the first half field of the wafer and the layouts of the patterns transferred to the second half field of the wafer are substantially the same as each other except for a boundary between the first and second half fields of the wafer.

6. The photolithography method as claimed in claim 4, wherein the photomask includes alignment keys in a portion of the scribe lane region at a central portion in the y-direction, the alignment keys being spaced apart from each other in the x-direction.

7. The photolithography method as claimed in claim 4, wherein both of a layout of a pattern at a lower end portion in the y-direction of the photomask and a layout of a pattern at an upper end portion in the y-direction of the photomask are transferred to a boundary between the first and second half fields of the wafer.

8. The photolithography method as claimed in claim 7, wherein the photomask includes:
first alignment keys spaced apart from each other in the x-direction in a portion of the scribe lane region at an upper end portion in the y-direction of the photomask; and
second alignment keys spaced apart from each other in the x-direction in a portion of the scribe lane region at a lower end portion in the y-direction of the photomask.

9. The photolithography method as claimed in claim 8, wherein:
both of layouts of the first alignment keys and the layouts of the second alignment keys are transferred to the boundary between the first and second half fields of the wafer, and
the first alignment keys and corresponding ones of the second alignment keys are disposed in the y-direction to form stitches.

10. The photolithography method as claimed in claim 8, wherein:
both of layouts of the first alignment keys and the layouts of the second alignment keys are transferred to the boundary between the first and second half fields of the wafer, and
the first and second alignment keys are alternately and repeatedly disposed in the x-direction to form a zipper.

11. The photolithography method as claimed in claim 1, wherein the light source generates EUV light.

12. The photolithography method as claimed in claim 1, wherein the photolithography system has a numerical aperture (NA) of 0.55.

13. The photolithography method as claimed in claim 1, wherein:
an etching object layer and a photoresist layer are sequentially stacked on the wafer,
the layouts of the patterns included in the photomask are transferred to the photoresist layer, and
the photolithography method further comprises, after performing the second exposure process:
performing a developing process on the photoresist layer to form a photoresist pattern; and
performing an etching process using the photoresist pattern as an etching mask to etch the etching object layer.

14. The photolithography method as claimed in claim 13, wherein:
the photomask includes chip regions and a scribe lane region surrounding the chip regions,
at least one of an alignment key, an overlay key and a test element group (TEG) is formed in the scribe lane region, and
etching the object layer includes forming at least one of an alignment key, an overlay key and a TEG on the wafer.

15. A photolithography method using a photolithography system including a light source, a photomask stage, a projection optical system and a wafer stage, horizontal directions substantially parallel to an upper surface or a lower surface of the photomask stage including x-direction and y-direction substantially perpendicular to each other, the projection optical system including an anamorphic lens having a reduction rate in the y-direction twice a reduction rate in the x-direction, and the method comprising:
after mounting a wafer and a photomask on the wafer stage and the photomask stage, respectively, performing a first exposure process using the photomask to transfer layouts of patterns included in the photomask to a first half field of the wafer; and
after changing a relative position of the photomask with respect to the wafer, performing a second exposure process to transfer the layouts of the patterns included in the photomask to a second half field of the wafer, the second exposure process using the same photomask without replacing the photomask, and the second half field being adjacent to the first field in the y-direction.

16. The photolithography method as claimed in claim 15, wherein each of the first and second half fields has an area corresponding to half an area of a field, the field being a region covered by a single exposure process if the projection optical system includes an isomorphic lens.

17. The photolithography method as claimed in claim 15, wherein the photomask includes chip regions spaced apart from each other in each of the x-direction and the y-direction and a scribe lane region surrounding the chip regions, and
wherein an alignment key, an overlay key or a test element group (TEG) is formed in the scribe lane region.

18. The photolithography method as claimed in claim 17, wherein the layouts of the patterns transferred to the first half field of the wafer and the layouts of the patterns transferred to the second half field of the wafer, except for a boundary between the first and second half fields of the wafer, are substantially the same as each other.

19. The photolithography method as claimed in claim 17, wherein the photomask includes alignment keys in a portion of the scribe lane region at a central portion in the y-direction, the alignment keys being spaced apart from each other in the x-direction.

20.-27. (canceled)

28. A photolithography method using a photolithography system including a light source, a photomask stage, a projection optical system and a wafer stage, the projection optical system including an anamorphic lens, and the method comprising:
after mounting a wafer and a photomask on the wafer stage and the photomask stage, respectively, performing a first exposure process using the photomask to transfer layouts of patterns included in the photomask to a first half field of the wafer; and
after changing a relative position of the photomask with respect to the wafer, performing a second exposure process to transfer the layouts of the patterns included in the photomask to a second half field of the wafer,
wherein the layouts of the patterns transferred to the first half field of the wafer and the layouts of the patterns transferred to the second half field of the wafer, except for a boundary between the first and second half fields of the wafer, are substantially the same as each other.

29.-55. (canceled)
